(19) United States
(12) Patent Application Publication
(10) Pub. No.: US 2025/0089418 A1
(43) Pub. Date: Mar. 13, 2025

(54) DISPLAY DEVICE AND METHOD FOR FABRICATING THE SAME

(71) Applicant: SAMSUNG DISPLAY CO., LTD., Yongin-si (KR)

(72) Inventors: Ki Chang EOM, Yongin-si (KR); Gwang Geun LEE, Yongin-si (KR); Ki Seong SEO, Yongin-si (KR); Yu Jin LEE, Yongin-si (KR); Jung An LEE, Yongin-si (KR)

(21) Appl. No.: 18/817,101

(22) Filed: Aug. 27, 2024

(30) Foreign Application Priority Data
Sep. 8, 2023 (KR) 10-2023-0119576

(51) Int. Cl. H01L 33/60; H01L 25/16; H01L 33/62

(52) U.S. Cl. CPC H10H 20/856; H01L 25/167; H10H 20/857; H10H 20/0363; H10H 20/0364

(57) ABSTRACT

A display device and a method of manufacturing a display device are disclosed. A display device includes a planarization layer including a first planarization part on a substrate, and a second planarization part and a third planarization part on the first planarization part, a first pad electrode on the second planarization part, and a second pad electrode on the third planarization part, an organic pattern layer on the first pad electrode and the second pad electrode, a light emitting element on the organic pattern layer, a partition wall, a reflective layer on a side of the partition wall and the first planarization part, a first auxiliary connection electrode connecting the second semiconductor layer and the first pad electrode, and a second auxiliary connection electrode connecting the first semiconductor layer and the second pad electrode, and the planarization layer has an undercut shape.

### CROSS-REFERENCE TO RELATED APPLICATION

The present application claims priority to and the benefit of Korean Patent Application No. 10-2023-0119576, filed on Sep. 8, 2023 in the Korean Intellectual Property Office, the entire disclosure of which is incorporated herein by reference.

### BACKGROUND

### 1. Field

Aspects of embodiments of the present disclosure relate to a display device and a method of manufacturing the same.

### 2. Description of the Related Art

Display devices are becoming increasingly important with the development of multimedia. In response to this, various types of display devices, such as organic light emitting displays (OLED) and liquid crystal displays (LCD), are being used.

A device for displaying an image of a display device includes a display panel, such as an organic light emitting display panel or a liquid crystal display panel. Among them, the light emitting display panel may include a light emitting element. For example, light emitting diodes (LED) include organic light emitting diodes that utilize organic materials as light emitting materials, inorganic light emitting diodes that utilize inorganic materials as light emitting materials, and the like.

### SUMMARY

According to aspects of embodiments of the present disclosure, a display device in which an auxiliary connection electrode and a reflective layer may be electrically separated from each other by adopting an undercut structure, and a manufacturing method for the display device in which the auxiliary connection electrode and the reflective layer are formed in a single process from a same material layer, are provided.

However, aspects of the present disclosure are not restricted to those set forth herein. The above and other aspects of the present disclosure will become more apparent to one of ordinary skill in the art to which the present disclosure pertains by referencing the detailed description of the present disclosure provided below.

According to one or more embodiments, a display device comprises a planarization layer including a first planarization part on a substrate, and a second planarization part and a third planarization part on the first planarization part, a first pad electrode on the second planarization part, and a second pad electrode on the third planarization part, an organic pattern layer on the first pad electrode and the second pad electrode, a light emitting element on the organic pattern layer and including a first semiconductor layer, an active layer, and a second semiconductor layer, a partition wall on a surface of the first planarization part and defining a space around the light emitting element, a reflective layer on a side of the partition wall and the first planarization part within the space, a first auxiliary connection electrode connecting the second semiconductor layer and the first pad electrode, and a second auxiliary connection electrode connecting the first semiconductor layer and the second pad electrode, and the planarization layer has an undercut shape in which a side surface of the second planarization part is recessed towards a center of the first pad electrode, and a side surface of the third planarization part is recessed towards a center of the second pad electrode.

In one or more embodiments, the reflective layer includes a first reflective layer disposed on a side of the partition wall and a second reflective layer disposed on an upper portion of the first planarization layer, wherein the second reflective layer extends from the first reflective layer and is disconnected from the first auxiliary connection electrode and the second auxiliary connection electrode by the undercut shape.

In one or more embodiments, the first auxiliary connection electrode and the second auxiliary connection electrode include a same material as the reflective layer.

In one or more embodiments, the first pad electrode and the second pad electrode are spaced apart from each other on a same plane and protrude outward from the light emitting element.

In one or more embodiments, the light emitting element further comprises an element reflective layer disposed on a bottom surface of the first semiconductor layer, an element insulating layer around (e.g., surrounding) sides of the element reflective layer, the first semiconductor layer, the active layer, and the second semiconductor layer, and a pad connection electrode disposed on a bottom surface of the element reflective layer, a first end of which is in direct contact with the second auxiliary connection electrode.

In one or more embodiments, the first auxiliary connection electrode includes a first end disposed on a top surface of the second semiconductor layer, extends along a side of the light emitting element and a side of the organic pattern layer, and further includes a second end disposed on a side of the first pad electrode, wherein the second auxiliary connection electrode has a first end disposed on the side of the light emitting element, extends along the side of the light emitting element, the first end of the pad connection electrode, and a side of the organic pattern layer, and further includes a second end disposed on a side of the second pad electrode.

In one or more embodiments, the display device further comprises a via layer and a wavelength conversion layer sequentially arranged in the space, wherein a height of the second auxiliary connection electrode is equal to or lower than a height of the via layer.

In one or more embodiments, the light emitting element further comprises a base substrate disposed on the second semiconductor layer, a first contact electrode disposed on a first surface of the second semiconductor layer, and a second contact electrode disposed on a first surface of the first semiconductor layer, and wherein the first contact electrode and the second contact electrode are arranged to be spaced apart from each other and are bonded to the organic pattern layer.

In one or more embodiments, the first auxiliary connection electrode includes a first end disposed on a side of the light emitting element, extends along the side of the light emitting element, a first end of the first contact electrode, and a side of the organic pattern layer, and further includes a second end disposed on a side of the first pad electrode, wherein the second auxiliary connection electrode includes a first end disposed on a side of the light emitting element, extends along the side of the light emitting element, a first end of the second contact electrode, and a side of the organic pattern layer, and further includes a second end disposed on a side of the second pad electrode.

In one or more embodiments, the display device further comprises a via layer and a wavelength conversion layer sequentially disposed in the space, wherein a height of the first auxiliary connection electrode and a height of the second auxiliary connection electrode are equal to or lower than a height of the via layer.

In one or more embodiments, the display device further comprises a via layer and a wavelength conversion layer sequentially disposed within the space and a capping layer, an overcoat layer, and a color filter layer sequentially disposed on the wavelength conversion layer and the partition wall.

According to one or more embodiments, a display device comprises a planarization layer including a first planarization part disposed on a substrate and a second planarization part and a third planarization part disposed on the first planarization part, a first pad electrode disposed on the second planarization part and a second pad electrode disposed on the third planarization part, a bank covering a portion of the first pad electrode and a portion of the second pad electrode, a first auxiliary connection electrode including a first end in contact with the first pad electrode and a second end disposed on a top surface of the bank, a second auxiliary connection electrode including a first end in contact with the second pad electrode and a second end disposed on the top surface of the bank, an insulating organic layer overlapping the first pad electrode and the second pad electrode and covering a portion of the first auxiliary connection electrode and a portion of the second auxiliary connection electrode, a light emitting element disposed on the insulating organic layer and having a first contact electrode and a second contact electrode on a top surface, and first and second lead lines respectively connecting the first contact electrode to the first auxiliary connection electrode and connecting the second contact electrode to the second auxiliary connection electrode, wherein the second planarization layer has an undercut shape in which a side surface of the second planarization part is recessed towards a center of the first pad electrode, and the third planarization part has an undercut shape in which a side surface of the third planarization part is recessed towards a center of the second pad electrode, and a horizontal reflective layer is located between the second planarization part and the third planarization part.

In one or more embodiments, the horizontal reflective layer is disposed between the first auxiliary connection electrode and the second auxiliary connection electrode and is disconnected from the first auxiliary connection electrode and the second auxiliary connection electrode by the undercut shape of the second planarization part and the undercut shape of the third planarization part.

In one or more embodiments, the horizontal reflective layer includes a same material as the first auxiliary connection electrode and the second auxiliary connection electrode.

In one or more embodiments, the light emitting element further comprises a first semiconductor layer, an active layer, a second semiconductor layer, and an element insulating layer, wherein the element insulating layer surrounds sides of the first semiconductor layer, the active layer, and the second semiconductor layer, wherein the first contact electrode is in contact with the first semiconductor layer, and the second contact electrode is in contact with the second semiconductor layer.

In one or more embodiments, a first end of the first lead line is disposed on the first contact electrode and a second end of the first lead line is disposed on the first auxiliary connection electrode, and a first end of the second lead line is disposed on the second contact electrode and a second end of the second lead line is disposed on the second auxiliary connection electrode.

According to one or more embodiments, a method of manufacturing display device comprises disposing a first planarization part, and a second planarization part and a third planarization part on the first planarization part, disposing a first pad electrode and a second pad electrode on the second planarization part and the third planarization part, etching the second planarization part and the third planarization part to expose the first planarization part, forming an undercut shape in which side surfaces of the second and third planarization parts are recessed towards centers of the first and second pad electrodes, disposing an organic pattern layer and a light emitting element on the first pad electrode and the second pad electrode, forming a partition wall on the first planarization part to be around (e.g., surround) the light emitting element, depositing a reflective material layer to cover both the partition wall and the light emitting element, forming a via layer in a space defined by the partition wall, forming a photoresist mask pattern to cover a portion of the light emitting element, and forming a first auxiliary connection electrode and a second auxiliary connection electrode and a reflective layer by etching a reflective material layer on the via layer and the photoresist mask pattern.

In one or more embodiments, the reflective layer includes a first reflective layer disposed on a side of the partition wall, and a second reflective layer disposed on an upper portion of the first planarization part, wherein the second reflective layer is disposed to extend from the first reflective layer and is disconnected from the first auxiliary connection electrode and the second auxiliary connection electrode by the undercut shape.

In one or more embodiments, the disposing of the organic pattern layer and the light emitting element on the first pad electrode and the second pad electrode includes: applying (e.g., fully applying) an organic pattern material layer on a substrate to cover the first planarization part, the second planarization part, the third planarization part, the first pad electrode, and the second pad electrode, disposing the light emitting element to overlap the first pad electrode and the second pad electrode on the organic pattern material layer, bonding the light emitting element by curing the organic pattern material layer and forming the organic pattern layer by ashing a portion of the organic pattern material layer not overlapping with the light emitting element.

In one or more embodiments, the method further comprises forming a wavelength conversion layer in the space defined by the partition wall, and forming an overcoat layer and a color filter layer sequentially disposed on the partition wall and the wavelength conversion layer.

The display device according to embodiments may form the auxiliary connecting electrode and the reflective layer in a single process using a same material layer and which may be electrically separated from each other by an undercut structure.

Further, the display device according to embodiments may improve light output efficiency and prevent (prevent or substantially prevent) color mixing by forming a reflector on a partition wall surrounding the light emitting element.

### BRIEF DESCRIPTION OF THE DRAWINGS

FIG. 1 is a perspective view illustrating a display device according to an embodiment.

FIGS. 2 and 3 are plan views illustrating a display device according to an embodiment.

FIG. 4 is a circuit diagram illustrating a first sub-pixel of a display panel according to an embodiment.

FIG. 5 is a circuit diagram illustrating a first sub-pixel of a display panel according to another embodiment.

FIG. 6 is a cross-sectional view schematically illustrating a display device according to an embodiment.

FIG. 7 is an enlarged view schematically illustrating a first light emitting region described with reference to FIG. 6.

FIG. 8 is an enlarged view of a region “A” of FIG. 7.

FIG. 9 is a view in which a plan view and a cross-sectional view of a light emitting element part according to the embodiment described with reference to FIG. 7 correspond to each other.

FIG. 10 is an enlarged view of a light emitting element according to an embodiment.

FIG. 11 is an enlarged view schematically illustrating a first light emitting region according to another embodiment, corresponding to the region of FIG. 7.

FIG. 12 is a cross-sectional view schematically illustrating a display device according to another embodiment.

FIG. 13 is an enlarged view schematically illustrating a first light emitting area described with reference to FIG. 12.

FIG. 14 is a plan view of the light emitting area explained with reference to FIG. 13.

FIG. 15 is an enlarged view of a light emitting element included in FIG. 13.

FIG. 16 is a cross-sectional view schematically illustrating a display device according to another embodiment.

FIG. 17 is an enlarged view schematically illustrating a first light emitting area described with reference to FIG. 16.

FIG. 18 is a plan view of a light emitting area explained with reference to FIG. 16.

FIG. 19 is an enlarged view of a light emitting element included in FIG. 17.

FIGS. 20 to 38 are diagrams to illustrate a method of manufacturing a display device according to an embodiment.

FIGS. 39 to 43 are diagrams to illustrate a manufacturing method of a display device according to another embodiment.

FIGS. 44 to 50 are diagrams to illustrate a manufacturing method of a display device according to another embodiment.

FIG. 51 is a diagram schematically showing an example of a virtual reality device including a display device according to an embodiment.

FIG. 52 is a diagram schematically showing an example of a smart device including a display device according to an embodiment.

FIG. 53 is a diagram schematically showing an example of a vehicle including a display device according to an embodiment.

FIG. 54 is a diagram schematically showing an example of a transparent display device including a display device according to an embodiment.

### DETAILED DESCRIPTION

Some embodiments will now be described more fully herein with reference to the accompanying drawings. The embodiments may, however, be provided in different forms and should not be construed as limiting the present disclosure. The same reference numbers indicate the same components throughout the disclosure. In the accompanying figures, thicknesses of layers and regions may be exaggerated for clarity.

Description of some parts which are not associated with the description may not be provided in order to more clearly describe embodiments of the present disclosure.

It is to be understood that when a layer is referred to as being “on” another layer or substrate, it may be directly on the other layer or substrate, or one or more intervening layers may also be present. In contrast, when an element is referred to as being “directly on” another element, there may be no intervening elements present.

Further, the phrase “in a plan view” refers to when an object portion is viewed from above, and the phrase “in a schematic cross-sectional view” refers to when a schematic cross-section taken by vertically cutting an object portion is viewed from a side. The terms “overlap” or “overlapped” mean that a first object may be above or below or to a side of a second object, and vice versa. Additionally, the term “overlap” may include layer, stack, face or facing, extending over, covering or partly covering, or any other suitable term as would be appreciated and understood by those of ordinary skill in the art. The expression “not overlap” include a meaning such as “apart from” or “set aside from” or “offset from” and any other suitable equivalents as would be appreciated and understood by those of ordinary skill in the art. The terms “face” and “facing” mean that a first object may directly or indirectly oppose a second object. In a case in which a third object intervenes between a first object and a second objects, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It is to be understood that the spatially relative terms are intended to encompass different orientations of the device in use or operation, in addition to the orientation depicted in the drawings. For example, in a case in which a device illustrated in the drawing is turned over, the device positioned “below” or “beneath” another device may be “above” another device. Accordingly, the illustrative term “below” may include both the lower and upper positions. The device may also be oriented in other directions and, thus, the spatially relative terms may be interpreted differently depending on the orientations.

When an element is referred to as being “connected” or “coupled” to another element, the element may be directly connected or directly coupled to the other element, or electrically connected or electrically coupled to the other element with one or more intervening elements interposed therebetween. It is to be further understood that when the terms “comprises,” “comprising,” “has,” “have,” “having,” “includes,” and/or “including” are used, they may specify the presence of stated features, integers, steps, operations, elements, and/or components, but do not preclude the presence or addition of other features, integers, steps, operations, elements, components, and/or any combination thereof.

It is to be understood that, although the terms “first,” “second,” “third,” or the like may be used herein to describe various elements, these elements are not to be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein are inclusive of the stated value and mean within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It is to be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Herein, some example embodiments of the present disclosure will be described in further detail with reference to the accompanying drawings.

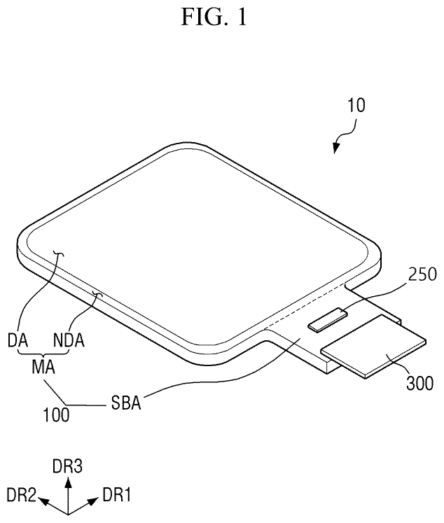

FIG. 1 is a perspective view illustrating a display device according to an embodiment.

Referring to FIG. 1, a display device 10 is a device for displaying video or still images, and may be used as a display screen of any one of portable electronic devices such as mobile phones, smartphones, tablet personal computers, smart watches, watch phones, mobile communication terminals, electronic notebooks, e-books, portable multimedia players (PMP), navigation, and ultra mobile PCs (UMPC), as well as a variety of products, such as televisions, laptops, monitors, billboards, and the internet of things (IOT) device.

The display device 10 may be a light-emitting display device, such as an organic light-emitting display device utilizing an organic light-emitting diode, a quantum dot light-emitting display device including a quantum dot light-emitting layer, an inorganic light-emitting display device including an inorganic semiconductor, and a miniaturized light-emitting display device utilizing a micro or nano light emitting diode (micro LED or nano LED). Herein, the provided description focuses on the display device 10 being a micro-light emitting display device, but the present disclosure is not limited thereto. Further, the subminiature light-emitting diode is described herein as a micro light-emitting diode for convenience of explanation.

In an embodiment, the display device 10 includes a display panel 100, a display driving circuit 250, and a circuit board 300.

In an embodiment, the display panel 100 may be formed having a rectangular-shaped plane having a short side in a first direction DR1 and a long side in a second direction DR2 that intersects the first direction DR1. A corner where the short side in the first direction DR1 and the long side in the second direction DR2 meet may be rounded to have a curvature (e.g., a predetermined curvature) or may be formed at a right angle. However, the planar shape of the display panel 100 is not limited to a rectangle, and may be formed in other polygonal, circular, or oval shapes. The display panel 100 may be formed flat but is not limited thereto. For example, the display panel 100 may be formed to include curved portions with a constant curvature or a changing curvature in left and right ends thereof. Additionally, the display panel 100 may be formed to be flexible, such as to be able to be bent, curved, folded, or rolled.

A substrate of the display panel 100 may include a main area MA and a sub-area SBA.

The main area MA may include a display area DA that displays an image and a non-display area NDA that is a peripheral area of the display area DA. The display area DA may include a plurality of pixels that display an image. For example, the pixel may include a first sub-pixel that emits first light, a second sub-pixel that emits second light, and a third sub-pixel that emits third light.

The sub-area SBA may protrude from one side of the main area MA in the second direction DR2. Although FIG. 1 illustrates the sub-area SBA being unfolded, the sub-area SBA may be bent, and, in this case, may be disposed on a bottom surface of the display panel 100. When the sub-area SBA is bent, it may overlap the main area MA in a third direction DR3, which is a thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached to the display panel 100 using a chip on glass (COG) method, a chip on plastic (COP) method, or an ultrasonic bonding method, but is not limited thereto. For example, the display driving circuit 250 may be attached to the circuit board 300 using a chip on film (COF) method.

The circuit board 300 may be attached to an end of the sub-area SBA of the display panel 100. As such, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible printed circuit board, a rigid printed circuit board, or a flexible film, such as a chip on film.

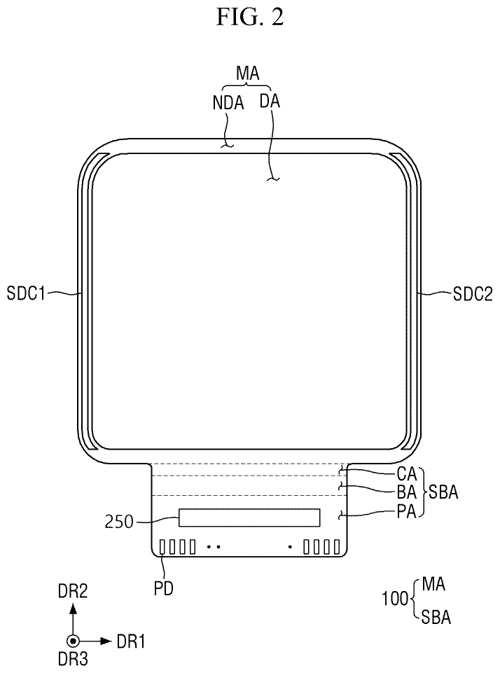

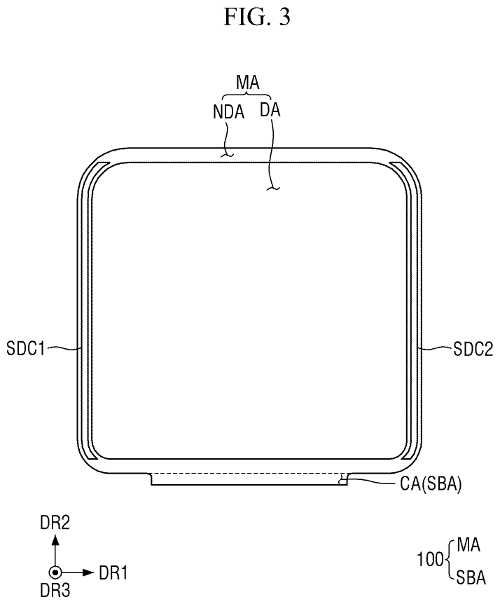

FIGS. 2 and 3 are plan views illustrating a display device according to an embodiment. FIG. 2 illustrates that the sub-area SBA is unfolded without being bent. FIG. 3 illustrates that the sub-area SBA is bent.

Referring to FIGS. 2 and 3, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be located in a center of the main area MA.

The non-display area NDA may be adjacent to the display area DA. The non-display area NDA may be an area outside the display area DA. In an embodiment, the non-display area NDA may be arranged to surround the display area DA. In an embodiment, the non-display area NDA may be an edge area of the display panel 100.

A first scan driving unit SDC1 and a second scan driving unit SDC2 may be disposed in the non-display area NDA. The first scan driving unit SDC1 is disposed on a side (for example, the left side) of the display panel 100, and the second scan driving unit SDC2 is disposed on another side (for example, the right side) of the display panel 100. However, the present disclosure is not limited to. Each of the first scan driving unit SDC1 and the second scan driving unit SDC2 may be electrically connected to the display driving circuit 250 through scan fan-out lines. Each of the first scan driving unit SDC1 and the second scan driving unit SDC2 may receive a scan control signal from the display driving circuit 250, generate scan signals according to the scan control signal, and output the scan signals to the scan lines.

The sub-area SBA may protrude from a side of the main area MA in the second direction DR2. A length of the sub-area SBA in the second direction DR2 may be smaller than a length of the main area MA in the second direction DR2. A length in the first direction DR1 of the sub-area SBA may be smaller than a length in the first direction DR1 of the main area MA or may be substantially equal to the length in the first direction DR1 of the main area MA. The sub-area SBA may be curved and may be disposed at the lower portion of the display panel 100. In this case, the sub-area SBA may overlap the main area MA in the third direction DR3.

The sub-area SBA may include a connection area CA, a pad area PA, and a bending area BA.

The connection area CA is an area protruding from a side of the main area MA in the second direction DR2. A side of the connection area CA may be in contact with the non-display area NDA of the main area MA, and another side of the connection area CA may be in contact with the bending area BA.

The pad area PA is an area where pads PD and the display driving circuit 250 are disposed. The display driving circuit 250 may be attached to the driving pads of the pad area PA using a conductive adhesive member, such as an anisotropic conductive film. The circuit board 300 may be attached to the pads PD of the pad area PA using a conductive adhesive member, such as an anisotropic conductive film. A side of the pad area PA may be in contact with the bending area BA.

The bending area BA is a bent or bendable area. When the bending area BA is bent, the pad area PA may be disposed below the connection area CA and below the main area MA. The bending area BA may be disposed between the connection area CA and the pad area PA. A side of the bending area BA may be in contact with the connection area CA, and another side of the bending area BA may be in contact with the pad area PA.

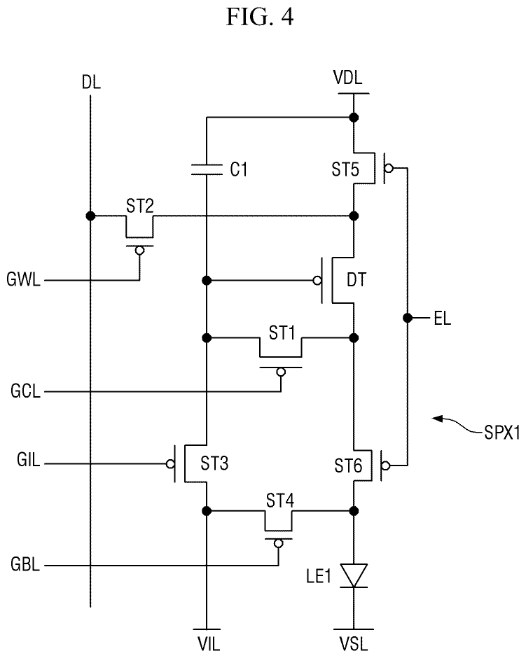

FIG. 4 is a circuit diagram illustrating a first sub-pixel of a display panel according to an embodiment.

Referring to FIG. 4, a first sub-pixel SPX1 according to an embodiment may be connected to scan lines GWL, GIL, GCL, and GBL, light emitting lines EL, and data lines DL. For example, the first sub-pixel SPX1 may be connected to a write scan line GWL, an initialization scan line GIL, a control scan line GCL, a bias scan line GBL, the light emitting line EL, and the data line DL.

The first sub-pixel SPX1 according to an embodiment includes a driving transistor DT, switch elements, a capacitor C1, and a first light emitting element LE1. The switch elements include first to sixth transistors ST1, ST2, ST3, ST4, ST5, and ST6.

The driving transistor DT includes a gate electrode, a first electrode, and a second electrode. The driving transistor DT controls a drain-source current (Ids, herein referred to as “driving current”) flowing between the first electrode and the second electrode according to a data voltage applied to the gate electrode.

In an embodiment, the first light emitting element LE1 may be a micro light-emitting diode.

The first light emitting element LE1 emits light according to the driving current (Ids). An amount of light emitted from the first light-emitting element LE1 may be proportional to the driving current (Ids). An anode electrode of the first light emitting element LE1 may be connected to a first electrode of the fourth transistor ST4 and a second electrode of the sixth transistor ST6, and a cathode electrode thereof may be connected to a second power supply line VSL to which a second power supply voltage is applied.

The capacitor C1 is formed between the second electrode of the driving transistor DT and the first power supply line VDL to which the first power supply voltage is applied. The first power supply voltage may be at a higher level than the second power supply voltage. An electrode of the capacitor C1 may be connected to the second electrode of the driving transistor DT, and another electrode thereof may be connected to the first power supply line VDL.

In an embodiment, as shown in FIG. 4, the first to sixth transistors ST1, ST2, ST3, ST4, ST5, and ST6 and the driving transistor DT may all be formed as p-type MOSFET. In an embodiment, the active layer of each of the first to sixth transistors ST1, ST2, ST3, ST4, ST5, and ST6 and the driving transistor DT may be formed of polysilicon or oxide semiconductor.

The gate electrode of the second transistor ST2 may be connected to the write scan line GWL, and the gate electrode of the first transistor ST1 may be connected to the control scan line GCL. The gate electrode of the third transistor ST3 may be connected to the initialization scan line GIL, and the gate electrode of the fourth transistor ST4 may be connected to the bias scan line GBL. In an embodiment, the first to sixth transistors ST1, ST2, ST3, ST4, ST5, and ST6 are formed as p-type MOSFET, and may be turned on when a scan signal of the gate low voltage and an emission signal are applied to the control scan line GCL, the write scan line GWL, the initialization scan line GIL, the bias scan line GBL, and the light emitting line EL, respectively. An electrode of the third transistor ST3 and an electrode of the fourth transistor ST4 may be connected to an initialization voltage line VIL.

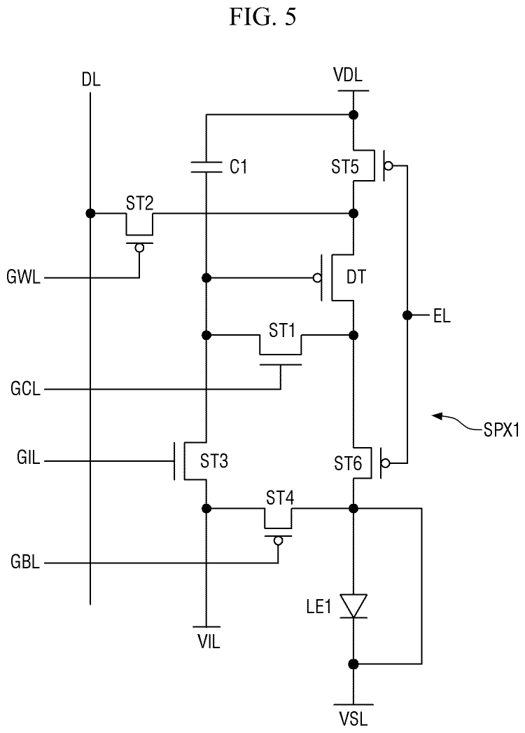

FIG. 5 is a circuit diagram illustrating a first sub-pixel of a display panel according to another embodiment.

Referring to FIG. 5, the driving transistor DT, the second transistor ST2, the fourth transistor ST4, the fifth transistor ST5, and the sixth transistor ST6 are formed of p-type MOSFET, and the first transistor ST1 and the third transistor ST3 may be formed as n-type MOSFET. An active layer of each of the driving transistor DT, the second transistor ST2, the fourth transistor ST4, the fifth transistor ST5, and the sixth transistor ST6 formed as the p-type MOSFET may be formed of polysilicon, and an active layer of each of the first transistor ST1 and the third transistor ST3 formed as the n-type MOSFET may be formed of the oxide semiconductor. In this case, transistors formed of polysilicon and transistors formed of oxide semiconductors may be arranged in different layers.

Since the first transistor ST1 and the third transistor ST3 are formed as n-type MOSFET, the first transistor ST1 may be turned on when a control scan signal with a gate high voltage is applied to the control scan line GCL, and the third transistor ST3 may be turned on when an initialization scan signal is applied to the initialization scan line GIL. In comparison, the second transistor ST2, the fourth transistor ST4, the fifth transistor ST5, and the sixth transistor ST6 are formed as p-type MOSFET, and may be turned on when a scan signal with a gate low voltage and an emission signal are applied to the write scan line GWL, the bias scan line GBL, and the light emitting line EL, respectively.

In another embodiment, the fourth transistor ST4 in FIG. 4 may be formed of the n-type MOSFET. In this case, the active layer of fourth transistor ST4 may be formed of the oxide semiconductor. When the fourth transistor ST4 is formed of n-type MOSFET, the fourth transistor ST4 may be turned on when a bias scan signal of a gate high voltage is applied to the bias scan line GBL.

In another embodiment, although not shown in FIGS. 4 and 5, the first to sixth transistors ST1, ST2, ST3, ST4, ST5, and ST6 and the driving transistor DT may all be formed as n-type MOSFET.

In an embodiment, a circuit diagram of the second sub-pixel and the third sub-pixel according to an embodiment are substantially the same as the circuit diagram of the first sub-pixel SPX1 described in conjunction with FIGS. 4 and 5, and a further description thereof will be omitted.

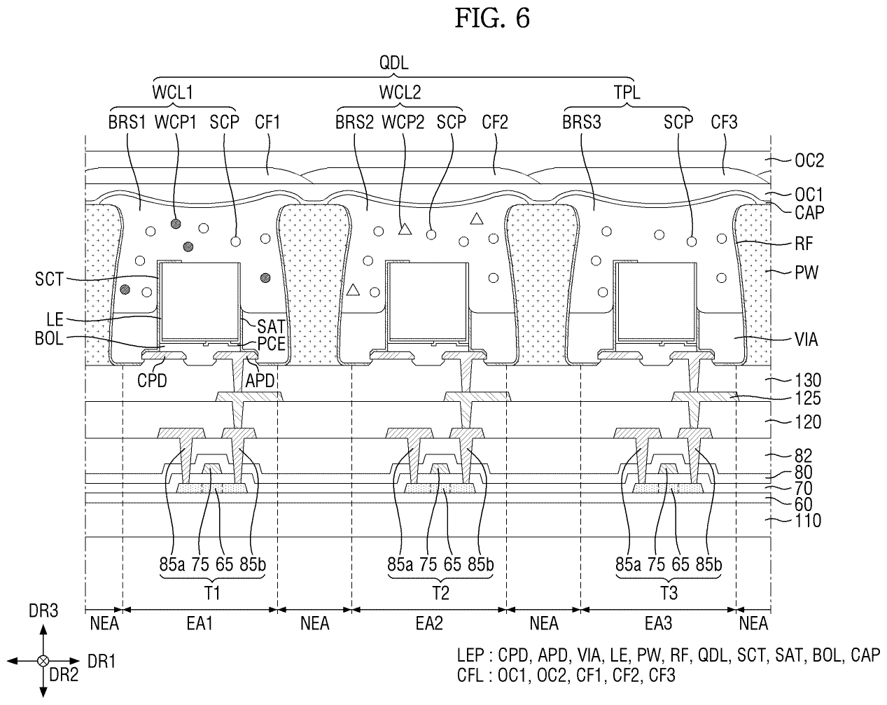

FIG. 6 is a cross-sectional view schematically illustrating a display device according to an embodiment.

Referring to FIG. 6, a display device 10 may include a substrate 110, a light emitting element part LEP, and a color filter layer CFL.

The substrate 110 may be an insulating substrate. The substrate 110 may include a transparent material. For example, the substrate 110 may include a transparent insulating material, such as glass, quartz, etc. The substrate 110 may be a rigid substrate. However, the substrate 110 is not limited thereto and may include a plastic, such as polyimide, and may have flexible characteristics that allow it to be curved, bent, folded, or rolled. A plurality of light emitting areas EA1, EA2, and EA3 and a non-light emitting area NEA may be defined in the substrate 110.

Switching elements T1, T2, and T3 may be located on the substrate 110. In an embodiment, a first switching element T1 may be located in the first light emitting area EA1 of the substrate 110, a second switching element T2 may be located in the second light emitting area EA2, and a third switching element T3 may be located in the third light emitting area EA3. However, the present disclosure is not limited thereto, and, in another embodiment, at least one of the first switching element T1, the second switching element T2, and the third switching element T3 may be located in the non-light emitting area NEA.

In an embodiment, the first switching element T1, the second switching element T2, and the third switching element T3 may each be a thin film transistor including amorphous silicon, polysilicon, or an oxide semiconductor. Although not shown in the drawing, a plurality of signal lines (eg, gate lines, data lines, power supply lines, etc.) that transmit signals to each switching element may be further positioned on the substrate 110.

Each switching element T1, T2, and T3 may include a semiconductor layer 65, a gate electrode 75, a source electrode 85a, and a drain electrode 85b.

A buffer layer 60 may be disposed on the substrate 110. The buffer layer 60 may be disposed to cover the entire surface of the substrate 110. The buffer layer 60 may include silicon nitride, silicon oxide, or silicon oxynitride, and may be made of a single layer or a double layer thereof.

The semiconductor layer 65 may be disposed on the buffer layer 60. The semiconductor layer 65 may form a channel for each switching element T1, T2, and T3. The semiconductor layer 65 may include amorphous silicon, polycrystalline silicon, or an oxide semiconductor. For example, the oxide semiconductor may include a binary compound (ABₓ), a ternary compound (ABₓC_{y}), or a quaternary compound (ABₓC_{y}D_{z}) containing, for example, indium, zinc, gallium, tin, titanium, aluminum, hafnium, zirconium, magnesium, and the like. In an embodiment, the semiconductor layer 65 may include indium tin gallium oxide (IGZO).

A gate insulating layer 70 may be disposed on the semiconductor layer 65. The gate insulating layer 70 may include a silicon compound, metal oxide, or the like. For example, the gate insulating layer 70 may include a silicon oxide, a silicon nitride, a silicon oxynitride, an aluminum oxide, a tantalum oxide, a hafnium oxide, a zirconium oxide, a titanium oxide, and the like. In an embodiment, the gate insulating layer 70 may include silicon oxide.

The gate electrode 75 may be disposed on the gate insulating layer 70. The gate electrode 75 may be disposed to overlap the semiconductor layer 65. The gate electrode 75 may include a conductive material. The gate electrode 75 may include a metal oxide, such as ITO, IZO, ITZO, In₂O₃, or a metal such as copper (Cu), titanium (Ti), aluminum (Al), molybdenum (Mo), tantalum (Ta), calcium (Ca), chromium (Cr), magnesium (Mg), or nickel (Ni). For example, the gate electrode 75 may be made of a Cu/Ti double layer in which an upper layer of copper is stacked on a lower layer of titanium but is not limited thereto.

A first interlayer insulating layer 80 and a second interlayer insulating layer 82 may be disposed on the gate electrode 75. The first interlayer insulating layer 80 may be directly disposed on the gate electrode 75, and the second interlayer insulating layer 82 may be directly disposed on the first interlayer insulating layer 80. The first interlayer insulating layer 80 and the second interlayer insulating layer 82 may each include an inorganic insulating material, such as any of silicon oxide, silicon nitride, silicon oxynitride, hafnium oxide, aluminum oxide, titanium oxide, tantalum oxide, zinc oxide, and the like. However, the present disclosure is not limited thereto, and the second interlayer insulating layer 82 may include an organic insulating material capable of flattening a lower-level difference. In an embodiment, two interlayer insulating layers, the first interlayer insulating layer 80 and the second interlayer insulating layer 82, are illustrated and described, but the present disclosure is not limited thereto, and, in an embodiment, only one interlayer insulating layer may be disposed.

The source electrode 85a and the drain electrode 85b may be disposed on the second interlayer insulating layer 82. The source electrode 85a and the drain electrode 85b may contact the semiconductor layer 65 through contact holes through the first interlayer insulation layer 80, the second interlayer insulation layer 82, and the gate insulation layer 70, respectively. The source electrode 85a and the drain electrode 85b may include metal oxides, such as ITO, IZO, ITZO, In₂O₃, or metals, such as any of copper (Cu), titanium (Ti), aluminum (Al), molybdenum (Mo), tantalum (Ta), calcium (Ca), chromium (Cr), magnesium (Mg), and nickel (Ni). For example, the source electrode 85a and the drain electrode 85b may be made of a Cu/Ti double layer in which an upper layer of copper is stacked on a lower layer of titanium, but is not limited thereto.

A first planarization layer 120 may be disposed on the first switching element T1, the second switching element T2, and the third switching element T3. The first planarization layer 120 may include an organic material. For example, the first planarization layer 120 may include acrylic resin, epoxy resin, imide resin, ester resin, etc. In an embodiment, the first planarization layer 120 may include a positive photosensitive material or a negative photosensitive material.

A pixel connection electrode 125 may be disposed on the first planarization layer 120. The pixel connection electrode 125 is disposed to correspond to each of the first switching element T1, the second switching element T2, and the third switching element T3, and may be electrically connected thereto. The pixel connection electrode 125 may connect pixel electrodes described later to the switching elements T1, T2, and T3 described above. The pixel connection electrode 125 may contact the switching elements T1, T2, and T3 through a contact hole penetrating the first planarization layer 120.

A second planarization layer 130 may be disposed on the first planarization layer 120 and the pixel connection electrode 125. The second planarization layer 130 flattens a lower-level difference and may include a same material as the first planarization layer 120 described above.

The light emitting element part LEP may be disposed on the second planarization layer 130. The light emitting element part LEP may include a first pad electrode CPD, a second pad electrode APD, an organic pattern layer BOL, a plurality of light emitting elements LE, a first auxiliary connection electrode SCT, a second auxiliary connection electrode SAT, a partition wall PW, a reflective layer RF, a via layer VIA, and a wavelength conversion layer QDL.

The first pad electrode CPD may be supplied with a first power supply voltage that is a low potential voltage and may be the cathode electrode. The second pad electrode APD may be directly connected to the pixel connection electrode 125 through the contact hole penetrating the second planarization layer 130, and electrically connected to each of the switching elements T1, T2, and T3 through the pixel connection electrode 125. The second pad electrode APD may be the anode electrode. The first pad electrode CPD and the second pad electrode APD may be formed as a single layer or multiple layers of any of molybdenum (Mo), aluminum (AI), chromium (Cr), gold (Au), titanium (Ti), nickel (Ni), neodymium (Nd), and copper (Cu), or an alloy thereof. In some embodiments, the first pad electrode CPD and the second pad electrode APD may have a two-layer structure of Ti/Al or a three-layer structure of Ti/Al/Ti. In some embodiments, each of the first pad electrode CPD and the second pad electrode APD may include a transparent conductive layer to increase adhesion. The transparent conductive layer may be formed of a transparent conductive oxide, such as indium tin oxide (ITO) and indium zinc oxide (IZO).

The organic pattern layer BOL may be disposed on the first pad electrode CPD and the second pad electrode APD. The organic pattern layer BOL may expose at least a portion of the first pad electrode CPD and the second pad electrode APD.

In an embodiment, the organic pattern layer BOL may be arranged in an island pattern shape in each light emitting area EA1, EA2, and EA3. For example, the organic pattern layer BOL disposed in each light emitting area EA1, EA2, and EA3 may be arranged to be spaced apart from the organic pattern layer BOL disposed in the adjacent light emitting area EA1, EA2, and EA3.

In an embodiment, a thickness of a plurality of organic pattern layers BOL may be about 2 μm or less but is not limited thereto.

The plurality of organic pattern layers BOL may include organic materials. The organic material may be, for example, a photosensitive organic insulating material, but is not limited thereto. In an embodiment, the organic material may include epoxy resin, acrylic resin, cardo resin, or imide resin.

The plurality of organic pattern layers BOL may be formed through various methods such as an organic imprinting method, an inkjet printing method, an electro-spray method, or a stamping method.

In a high-resolution display panel, such as the display device 10 in an embodiment, it is difficult to replace the organic pattern layer BOL with an anisotropic conductive film (ACF).

The light emitting element LE may be disposed on the organic pattern layer BOL. The light emitting elements LE may be inorganic light emitting elements made of inorganic materials, such as GaN.

The light emitting elements LE may be disposed in each of the first light emitting area EA1, the second light emitting area EA2, and the third light emitting area EA3. The light emitting element LE may be a vertical light emitting diode element extending long in the third direction DR3. That is, a length of the light emitting element LE in the third direction DR3 may be longer than a length thereof in the horizontal direction. The length in the horizontal direction indicates a length in the first direction DR1 or a length in the second direction DR2. For example, the length of the light emitting element LE in the first direction DR1 or the length in the second direction DR2 may be approximately 7 μm to 10 μm, but is not limited thereto. In an embodiment, the length of the light emitting element LE in the third direction DR3 may be approximately 1 μm to 5 μm. However, the present disclosure is not limited to this, and the length of the light emitting element LE in the third direction DR3 may be equal to or smaller than the length thereof in the horizontal direction.

The light emitting element LE may be a micro light emitting diode element.

The partition wall PW and the via layer VIA that compartmentalize each light emitting area EA1, EA2, and EA3 may be further disposed on the second planarization layer 130.

The partition wall PW may compartmentalize a plurality of light emitting areas EA1, EA2, and EA3. The partition wall PW is arranged to extend in the first direction DR1 and the second direction DR2 and may be formed in a grid-like pattern throughout the display area DA. In an embodiment, the partition wall PW may not overlap with the plurality of light emitting areas EA1, EA2, and EA3 and may overlap with the non-light emitting area NEA.

The partition wall PW may provide a space for the wavelength conversion layer QDL to be formed. The partition wall PW may be made to be relatively thick to provide the space in which the wavelength conversion layer QDL is formed. The partition wall PW may include an organic insulating material so as to be made to be thick. The organic insulating material may include, for example, epoxy-based resin, acrylic-based resin, cardo-based resin, or imide-based resin.

In an embodiment, the partition wall PW may block the transmission of light in the non-light emitting area NEA. The partition wall PW may further include a light blocking material and may include a dye or pigment having light blocking properties. For example, the partition wall PW may be a black matrix. External light incident from the outside of the display device 10 may cause a problem that distorts a color gamut of the light emitting element part LEP. According to an embodiment, the partition wall PW including the light blocking material is disposed in the light emitting element part LEP such that at least a portion of external light may be absorbed by the light blocking member. Therefore, color distortion caused by external light reflection may be reduced. Further, the partition wall PW including the light blocking material may prevent or substantially prevent color mixing from occurring due to light intrusion between adjacent light emitting areas, thereby further improving color reproduction. In an embodiment, the partition wall PW is formed as a single layer, but the present disclosure is not limited thereto, and the partition wall PW may be formed as a two-layer structure. A height of the partition wall PW may be higher than a height of the light emitting element LE. In an embodiment, the height of the partition wall PW may be about 8 to 14 μm. The height of the partition wall PW may refer to a length from the top of the second planarization layer 130 in the third direction DR3.

In an embodiment, the partition wall PW is formed of negative photoresist and may have an inverted tapered shape.

The reflective layer RF may be disposed between the partition wall PW and a space formed by the partition wall PW. The reflective layer RF may be disposed on a side of the partition wall PW, and a bottom surface between the partition walls PW which is not overlapped with the light emitting element LE, the first pad electrode CPD and the second pad electrode APD. The reflective layer RF may include an opening formed in an area overlapping the first pad electrode CPD, the second pad electrode APD, and the light emitting element LE. In an embodiment, the reflective layer RF may include a metal material with high light reflectance. For example, the reflective layer RF may include aluminum or silver, or an alloy thereof.

The first auxiliary connection electrode SCT is disposed along a side of the light emitting element LE and connects the second semiconductor layer SEM2, which will be described later, and the first pad electrode CPD of the light emitting element LE. The first auxiliary connection electrode SCT includes the conductive material and may directly contact the second semiconductor layer SEM2 and the first pad electrode CPD.

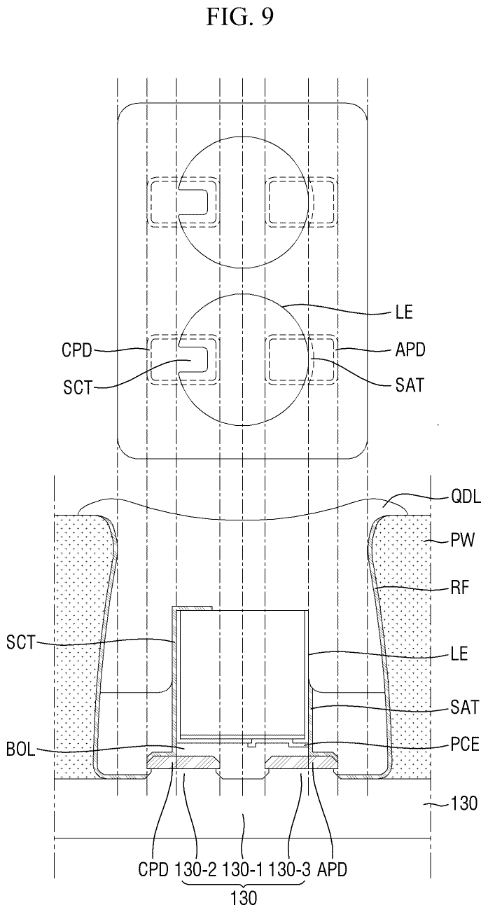

The second auxiliary connection electrode SAT is disposed along the side of the light emitting element LE and connects a pad connection electrode PCE of the light emitting element LE and the second pad electrode APD. The second auxiliary connection electrode SAT includes the conductive material and directly contacts the pad connection electrode PCE and the second pad electrode APD. Referring to FIG. 9, the pad connection electrode PCE and the second pad electrode APD are arranged to be spaced apart from each other.

The via layer VIA may be disposed in each of the light emitting areas EA1, EA2, and EA3 compartmentalized by the partition wall PW. The via layers VIA arranged in each of the light emitting areas EA1, EA2, and EA3 may be arranged to be spaced apart from each other. The via layers VIA may be arranged in a space between each of the plurality of sub-pixels, forming an island pattern spaced apart from each other. In other words, the via layer VIA may be disposed on the second planarization layer 130. The via layer VIA may not surround the entire light emitting element LE but may be disposed to cover the first and second pad electrodes CPD and APD that protrude to the outside of the light emitting element LE.

The via layer VIA may be formed lower than the height of the light emitting element LE. In an embodiment, a height of the via layer VIA may be the same as that of the second auxiliary connection electrode SAT. The height of the via layer VIA may be higher than the height of the second auxiliary connection electrode SAT.

The via layer VIA may be formed of an organic film, such as acryl resin, epoxy resin, phenolic resin, polyamide resin, polyimide resin, or the like.

The wavelength conversion layer QDL may be disposed on the via layer VIA. The wavelength conversion layer QDL may convert or shift a peak wavelength of incident light into light of another specific peak wavelength and emit the light. The wavelength conversion layer QDL may convert blue first light emitted by the light emitting element LE into red second light, convert the blue first light into green third light, or transmit the blue first light as is.

The wavelength conversion layer QDL may be disposed in each of the light emitting areas EA1, EA2, and EA3 compartmentalized by the partition wall PW and may be disposed to be spaced apart from each other. That is, the wavelength conversion layer QDL may be formed in an island pattern spaced apart from each other. The wavelength conversion layer QDL may be disposed to overlap the first light emitting area EA1, the second light emitting area EA2, and the third light emitting area EA3, respectively. In an embodiment, each of the wavelength conversion layer QDL may completely overlap the first light emitting area EA1, the second light emitting area EA2, and the third light emitting area EA3.

The wavelength conversion layer QDL includes a first wavelength conversion pattern WCL1 overlapping with the first light emitting area EA1, a second wavelength conversion pattern WCL2 overlapping with the second light emitting area EA2, and a light transmission pattern TPL overlapping the third light emitting area EA3.

The first wavelength conversion pattern WCL1 may be disposed to overlap the first light emitting area EA1. The first wavelength conversion pattern WCL1 may convert or shift the peak wavelength of incident light into light of another specific peak wavelength and emit the light. In an embodiment, the first wavelength conversion pattern WCL1 may convert and emit blue first light emitted from the light emitting element LE of the first light emitting area EA1 into second light, which is red light having a single peak wavelength in a range of about 610 nm to about 650 nm.

The first wavelength conversion pattern WCL1 may include a first base resin BRS1, a first wavelength conversion particle WCP1, and a scatterer SCP. The first base resin BRS1 may include a light-transmitting organic material. For example, the first base resin BRS1 may include epoxy-based resin, acrylic-based resin, cardo-based resin, or imide-based resin.

The first wavelength conversion particle WCP1 may convert the first light incident from the light emitting element LE into the second light. For example, the first wavelength conversion particle WCP1 may convert light in the blue wavelength band into light in the red wavelength band. The first wavelength conversion particle WCP1 may be a quantum dot (QD), a quantum rod, a fluorescent material, or a phosphorescent material. For example, quantum dots may be particulate materials that emit a specific color as electrons transition from the conduction band to the valence band.

The quantum dots may be semiconductor nanocrystalline materials. Depending on a composition and size thereof, the quantum dot may have a specific bandgap to absorb light and emit light with a unique wavelength. Examples of the semiconductor nanocrystals of the quantum dots include IV group nanocrystals, II-VI group compound nanocrystals, III-V group compound nanocrystals, IV-VI group compound nanocrystals, or combinations thereof.

In an embodiment, the group II-VI compound is a binary compound selected from the group consisting of CdSe, CdTe, ZnS, ZnSe, ZnTe, ZnO, HgS, HgSe, HgTe, MgSe, MgS, and mixtures thereof; a ternary compound selected from the group consisting of InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and mixtures thereof.

In an embodiment, the group III-V compound is a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAS, AlPSb, InGaP, InNP, InAlP, InNAs, InNSb, InPAs, InPSb, and mixtures thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof.

In an embodiment, the group IV-VI compounds may be selected from the group consisting of binary compounds selected from the group consisting of SnS, SnSe, SnTe, PbS, PbSe, PbTe, and mixtures thereof; ternary compounds selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof. The group IV element may be selected from the group consisting of Si, Ge, and mixtures thereof. The group IV compound may be a binary compound selected from the group consisting of SiC, SiGe, and mixtures thereof.

The binary, ternary, or quaternary compounds may be present in the particle at a uniform concentration or may be present in the same particle with a partially different concentration distribution. The quantum dot may also have a core-shell structure in which a quantum dot surrounds another. An interface of the core and shell may have a concentration gradient in which a concentration of an element present in the shell decreases toward the center.

In an embodiment, the quantum dot may have a core-shell structure including a core including a nanocrystal as described above and a shell surrounding the core. The shell of the quantum dot may act as a protective layer to prevent or substantially prevent chemical denaturation of the core to maintain semiconductor properties and/or as a charging layer to impart electrophoretic properties to the quantum dot. The shell may be monolayer or multilayer. Examples of shells for the quantum dots include oxides of metals or non-metals, semiconductor compounds, or combinations thereof.

For example, the oxides of said metals or non-metals may be, for example, any of binary compounds, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or ternary compounds, such as MgAl₂O₄, CoFe₂O₄, NiFe₂O₄, CoMn₂O₄, but the present disclosure is not limited thereto.

In an embodiment, the semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but are not limited thereto.

The second wavelength conversion pattern WCL2 may be disposed to overlap the second light emitting area EA2. The second wavelength conversion pattern WCL2 may emit light by converting or shifting the peak wavelength of incident light into light of another specific peak wavelength. In an embodiment, the second wavelength conversion pattern WCL2 converts the blue first light emitted from the light emitting element LE of the second light emitting area EA2 into green third light having a peak wavelength in a range of about 510 nm to 550 nm and emit the light.

The second wavelength conversion pattern WCL2 may include a second base resin BRS2 and a second wavelength conversion particle WCP2 and the scatterer SCP dispersed in the second base resin BRS2.

The second base resin BRS2 may be made of a material with high light transmittance, may be made of a same material as the first base resin BRS1, or may include at least one of the materials described as an example as constituent materials.

The second wavelength conversion particle WCP2 may convert or shift the peak wavelength of incident light to another specific peak wavelength. In an embodiment, the second wavelength conversion particle WCP2 may convert the blue first light provided from the light emitting element LE into green third light having a peak wavelength in a range of about 510 nm to 550 nm and emit the light. Examples of the second wavelength conversion particle WCP2 include quantum dots, quantum rods, or phosphors. The second wavelength conversion particle WCP2 may be substantially the same as or similar to that described above in the description of the first wavelength conversion particle WCP1, and further description thereof will be omitted.

The light transmission pattern TPL may be arranged to overlap the third light emitting area EA3. The light transmission pattern TPL may transmit incident light. The light transmission pattern TPL may directly transmit the blue first light emitted from the light emitting element LE disposed in the third light emitting area EA3. The light transmission pattern TPL may include a third base resin BRS3 and the scatterer SCP dispersed in the third base resin BRS3. The third base resin BRS3 may be substantially the same as or similar to the above-described first base resin BRS1, and further description thereof will be omitted.

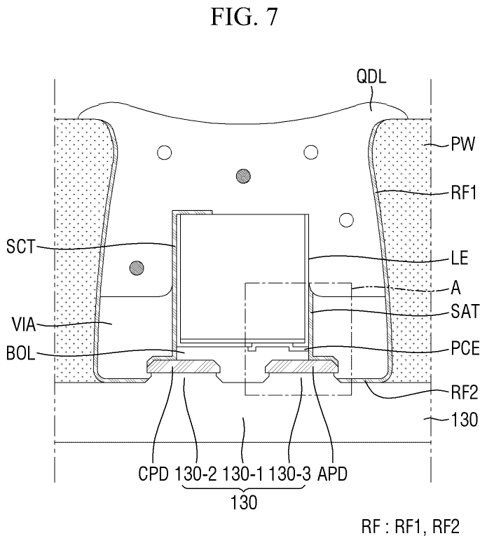

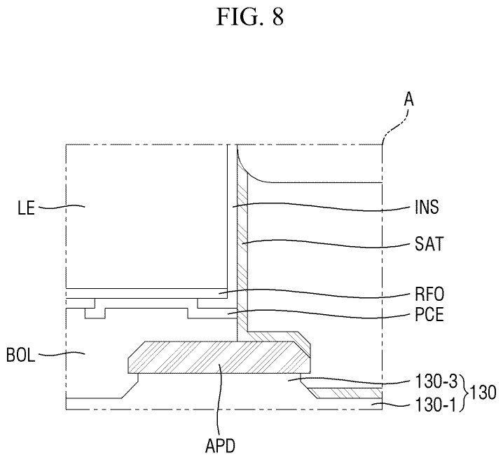

The light emitting element part LEP is described in further detail with reference to FIGS. 7 and 8.

The first light, second light, and third light emitted from the below-described light emitting element part LEP may be transmitted through the color filter layer CFL described herein to realize full color.

A capping layer CAP may be disposed on the partition wall PW and the wavelength conversion layer QDL, and may be included in the light emitting element part LEP. The capping layer CAP covers the lower wavelength conversion layer QDL to protect the lower wavelength conversion layer QDL from moisture or debris. In an embodiment, the capping layer CAP may include an inorganic material. For example, the capping layer CAP may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. The drawing illustrates that the capping layer CAP is formed as one layer, but the present disclosure is not limited thereto. For example, the capping layer CAP may be formed as multiple layers stacked with alternating inorganic layers including at least one of the materials exemplified as materials that the capping layer CAP may include. In an embodiment, the thickness of the capping layer CAP may be in a range from 0.05 μm to 2 μm but is not limited thereto.

The color filter layer CFL may be disposed on the light emitting element part LEP. The color filter layer CFL may include a first overcoat layer OC1, a first color filter CF1, a second color filter CF2, a third color filter CF3, and a second overcoat layer OC2.

The first overcoat layer OC1 may be disposed on the light emitting element part LEP. In an embodiment, the first overcoat layer OC1 may be directly disposed on the capping layer CAP of the light emitting element part LEP. In an embodiment, the first overcoat layer OC1 may be disposed entirely in the display area DA and may have a flat surface. The first overcoat layer OC1 may facilitate formation of the color filter layer CFL by flattening a step formed by the lower wavelength conversion layer QDL.

The first overcoat layer OC1 may include a light-transmitting organic material. For example, the first overcoat layer OC1 may include epoxy resin, acrylic resin, cardo resin, or imide resin. In an embodiment, the first overcoat layer OC1 is illustrated as a single layer, but is not limited thereto and may be arranged to be stacked in multiple layers.

The first color filter CF1, the second color filter CF2, and the third color filter CF3 may be disposed on the first overcoat layer OC1. The first color filter CF1 may be disposed in the first light emitting area EA1, the second color filter CF2 may be disposed in the second light emitting area EA2, and the third color filter CF3 may be disposed in the third light emitting area EA3.

The first color filter CF1, the second color filter CF2, and the third color filter CF3 may include a colorant, such as a dye or pigment that absorbs wavelengths other than the corresponding color wavelength. The first color filter CF1 may selectively transmit the second light (e.g., red light) and block or absorb the first light (e.g., blue light) and the third light (e.g., green light). The second color filter CF2 may selectively transmit the third light (e.g., green light) and block or absorb the first light (e.g., blue light) and the second light (e.g., red light). The third color filter CF3 may selectively transmit the first light (e.g., blue light) and block or absorb the second light (e.g., red light) and the third light (e.g., green light). For example, the first color filter CF1 may be a red color filter, the second color filter CF2 may be a green color filter, and the third color filter CF3 may be a blue color filter.

In an embodiment, the light incident on the first color filter CF1 may be light converted to second light in the first wavelength conversion pattern WCL1, the light incident on the second color filter CF2 may be light converted to third light in the second wavelength conversion pattern WCL2, and the light incident on the third color filter CF3 may be first light transmitted through the light transmission pattern TPL. As a result, the second light transmitted through the first color filter CF1, the third light transmitted through the second color filter CF2, and the first light transmitted through the third color filter CF3 may be emitted towards the top of the substrate 110 to achieve full color.

The first color filter CF1, the second color filter CF2, and the third color filter CF3 may absorb a portion of the light entering from the outside of the display device 10 to reduce the reflected light caused by external light. Accordingly, the first color filter CF1, the second color filter CF2, and the third color filter CF3 may prevent or substantially prevent color distortion due to reflection of external light.

A planar area of the first color filter CF1, the second color filter CF2, and the third color filter CF3 may be larger than a planar area of the corresponding one of the plurality of light emitting areas EA1, EA2, and EA3. For example, the first color filter CF1 may be larger than the planar area of the first light emitting area EA1, the second color filter CF2 may be larger than the planar area of the second light emitting area EA2, and the third color filter CF3 may be larger than the planar area of the third light emitting area EA3. However, the present disclosure is not limited thereto, and, for example, the planar area of the first color filter CF1, the second color filter CF2, and the third color filter CF3 may be equal to the planar area of the corresponding one of the plurality of light emitting areas EA1, EA2, and EA3.

The second overcoat layer OC2 may be disposed on the first color filter CF1, the second color filter CF2, and the third color filter CF3. In an embodiment, the second overcoat layer OC2 may be directly disposed on the first color filter CF1, the second color filter CF2, and the third color filter CF3. In an embodiment, the second overcoat layer OC2 may be disposed entirely in the display area DA and may have a flat surface. The second overcoat layer OC2 may flatten a step formed by the lower the first color filter CF1, the second color filter CF2, and the third color filter CF3. The second overcoat layer OC2 may include a light-transmitting organic material and may be substantially the same as or similar to the first overcoat layer OC1 described above.

As described above, the display device 10 according to an embodiment may improve light emission efficiency of the light emitting element LE by forming the reflective layer RF on the side of the partition wall PW and on the substrate 110 in a region not overlapping with the light emitting element LE between the partition wall PW and another partition wall PW.

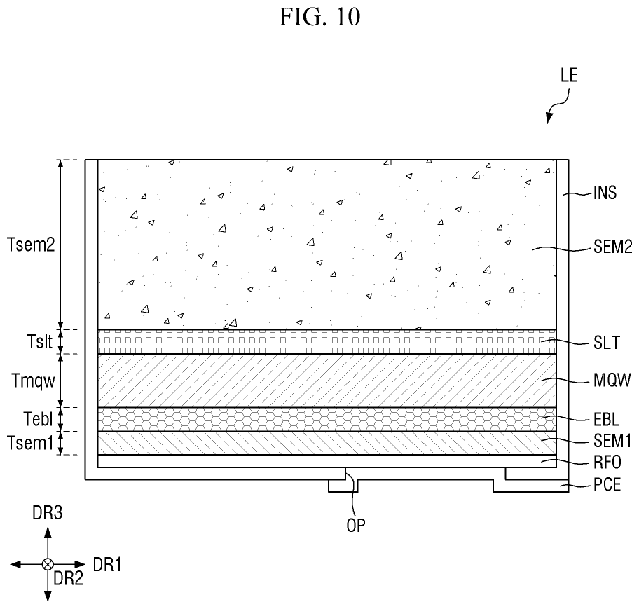

FIG. 7 is an enlarged view schematically illustrating the first light emitting region described with reference to FIG. 6. FIG. 8 is an enlarged view of a region “A” of FIG. 7. FIG. 9 is a view in which a plan view and a cross-sectional view of a light emitting element part according to the embodiment described with reference to FIG. 7 correspond to each other. FIG. 10 is an enlarged view of a light emitting element according to an embodiment.

Referring to FIGS. 7 to 9, the second planarization layer 130 may have an undercut structure in a portion overlapping the first pad electrode CPD and the second pad electrode APD. For example, the second planarization layer 130 includes a first planarization part 130-1 disposed on the substrate 110, a second planarization part 130-2 disposed on the first planarization part 130-1, and a third planarization part 130-3 disposed on the first planarization part 130-1. The second planarization part 130-2 and the third planarization part 130-3 may be arranged to be spaced apart from each other on a same plane. The second planarization part 130-2 may overlap the first pad electrode CPD, and the third planarization part 130-3 may overlap the second pad electrode APD.

The second planarization layer 130 has an undercut-shape in which a side surface of the second planarization part 130-2 is located inwardly from a side surface of the first pad electrode CPD, and a side surface of the third planarization part 130-3 is located inwardly from a side surface of the second pad electrode APD.

The organic pattern layer BOL is disposed between the first pad electrode CPD and the second pad electrode APD and may cover a portion of the first pad electrode CPD and a portion of the second pad electrode APD. The organic pattern layer BOL may be disposed between the first pad electrode CPD and the second pad electrode APD to fill a space between the second planarization part 130-2 and the third planarization part 130-3 having the undercut structure.

The light emitting element LE may be disposed on the organic pattern layer BOL. In an embodiment, the side surface of the organic pattern layer BOL may be disposed in a straight line with the side surface of the light emitting element LE.

The light emitting element LE may include the pad connection electrode PCE.

The pad connection electrode PCE may be disposed on a bottom surface of the light emitting element LE. The pad connection electrode PCE is disposed on the bottom surface of the light emitting element LE and may be disposed equal to or less than a width of the light emitting element LE. A side of the pad connection electrode PCE may be disposed on a straight line with a side of the light emitting element LE. The pad connection electrode PCE may be disposed in an area that overlaps the second pad electrode APD. A side of the pad connection electrode PCE may be disposed in a straight line with a side of the organic pattern layer BOL.

The pad connection electrode PCE may be formed from any of, but not limited to, molybdenum (Mo), aluminum (AI), chromium (Cr), gold (Au), titanium (Ti), nickel (Ni), neodymium (Nd), and copper (Cu).

The first auxiliary connection electrode SCT connecting the top of the light emitting element LE and the first pad electrode CPD may be disposed along the side of the light emitting element LE. An end of the first auxiliary connection electrode SCT is disposed on a top surface of the light emitting element LE, and another end of the first auxiliary connection electrode SCT is disposed on a side of the first pad electrode CPD. When the side of the first pad electrode CPD protrudes outward from the side of the light emitting element LE, the first auxiliary connection electrode SCT may be disposed on the top surface and the side of the first pad electrode CPD that protrudes outwardly from the side of the light emitting element LE. Accordingly, the contact area between the first auxiliary connection electrode SCT and the first pad electrode CPD may be wider. As such, the first auxiliary connection electrode SCT extends from the top surface of the light emitting element LE along the side of the light emitting element LE and along the side of the organic pattern layer BOL and is disposed along at least a portion of the top surface and side of the first pad electrode CPD.

Although the first auxiliary connection electrode SCT is disposed on a portion of the top surface of the light emitting element LE, as can be seen with reference to FIG. 9, the first auxiliary connection electrode SCT covers a relatively small portion of the top surface of the light emitting element LE, such that the use of a transparent electrode does not significantly affect the light emission effect of the light emitting element LE.

The first pad electrode CPD may be supplied with a low-potential power supply voltage. The light emitting element LE may receive the power supply voltage input through the first pad electrode CPD through the first auxiliary connection electrode SCT.

The second auxiliary connection electrode SAT connecting the pad connection electrode PCE and the second pad electrode APD may be disposed on another side of the light emitting element LE. The second auxiliary connection electrode SAT and the first auxiliary connection electrode SCT may be arranged to face each other with the light emitting element LE in between but are not limited thereto.

An end of the second auxiliary connection electrode SAT is disposed on the side of the light emitting element LE, and another end of the second auxiliary connection electrode SAT is disposed on a side of the second pad electrode APD. That is, the second auxiliary connection electrode SAT extends from the side of the light emitting element LE to the end of the second pad electrode APD, along the side of the organic pattern layer BOL, and along at least a portion of the top surface and side of the second pad electrode APD. A height of the second auxiliary connection electrode SAT may be the same as a height of the via layer VIA. When the side of the second pad electrode APD protrudes outward from the side surface of the light emitting element LE, the second auxiliary connection electrode SAT may be disposed on the top surface and sides of the second pad electrode APD that protrude outwardly from the sides of the light emitting element LE. Thus, the contact area of the second auxiliary connection electrode SAT with the second pad electrode APD may be larger.

The second pad electrode APD may be supplied with a pixel voltage or an anode voltage.

The pad connection electrode PCE may be supplied with the pixel voltage or anode voltage input through the second pad electrode APD through the second auxiliary connection electrode SAT. The light emitting elements LE may emit light with a luminance (e.g., a predetermined luminance) depending on a voltage difference between the pixel voltage and the power supply voltage.

As will be described later, the first auxiliary connection electrode SCT and the second auxiliary connection electrode SAT may be formed through a same process as the reflective layer RF disposed on the side of the partition wall PW. Accordingly, the first auxiliary connection electrode SCT and the second auxiliary connection electrode SAT may include a same material as the reflective layer RF. For example, the first auxiliary connection electrode SCT and the second auxiliary connection electrode SAT may include aluminum or silver, which are metal materials with high light reflectivity, or may include alloys thereof.

The reflective layer RF may include a first reflective layer RF1 around (e.g., surrounding) the side of the partition wall PW and a second reflective layer RF2 disposed on a flat surface between the partition wall PW and the light emitting element LE. In an embodiment, the first reflective layer RF1 and the second reflective layer RF2 may be continuously connected.

The reflective layer RF is disposed to be spaced apart from the first pad electrode CPD and the second pad electrode APD by the second planarization part 130-2 and the third planarization part 130-3 having the undercut structure. Further, the reflective layer RF is spaced apart from the first auxiliary connection electrode SCT and the second auxiliary connection electrode SAT by the second and third planarization parts 130-2 and 130-3 of the undercut structure.

The via layer VIA and the wavelength conversion layer QDL may be sequentially disposed in the space formed by the partition wall PW.

The via layer VIA may be disposed on the second reflective layer RF2 disposed on the first planarization part 130-1.

A height of the via layer VIA may be lower than a height of the light emitting element LE, and a thickness of the via layer VIA may be thinner than a thickness of the wavelength conversion layer QDL. The height of the via layer VIA may refer to a length from a top surface of the second reflective layer RF2 in the third direction DR3. The thickness of the via layer VIA may refer to a length from a bottom surface to a top surface of the via layer VIA. Similarly, the thickness of the wavelength conversion layer QDL may refer to a length from a bottom surface to a top surface of the wavelength conversion layer QDL.

As shown in FIG. 10, in an embodiment, the light emitting element LE includes a first semiconductor layer SEM1, an electron blocking layer EBL, an active layer MQW, a superlattice layer SLT, and a second semiconductor layer SEM2 in the third direction DR3. The first semiconductor layer SEM1, the electron blocking layer EBL, the active layer MQW, the superlattice layer SLT, and the second semiconductor layer SEM2 may be stacked sequentially in the third direction DR3.

The first semiconductor layer SEM1 may be doped with a first conductivity type dopant, such as Mg, Zn, Ca, Sr, or Ba. For example, the first semiconductor layer SEM1 may be p-GaN doped with p-type Mg. In an embodiment, a thickness Tsem1 of the first semiconductor layer SEM1 may be approximately 30 to 200 nm.

The electron blocking layer EBL may be disposed on the first semiconductor layer SEM1. The electron blocking layer EBL may be a layer for suppressing or preventing (preventing or substantially preventing) too many electrons from flowing into the active layer MQW. For example, the electron blocking layer EBL may be p-AlGaN doped with p-type Mg. In an embodiment, a thickness Tebl of the electron blocking layer EBL may be approximately 10 nm to 50 nm. However, in an embodiment, the electron blocking layer EBL may be omitted.

The active layer MQW may be disposed on the electron blocking layer EBL. The active layer MQW may emit light by recombining electron-hole pairs according to electrical signals applied through the first semiconductor layer SEM1 and the second semiconductor layer SEM2. The active layer MQW may emit first light having a central wavelength range of 450 nm to 495 nm, that is, light in the blue wavelength band.

The active layer MQW may include a material having a single or multi-quantum well structure. When the active layer MQW includes a material having a multi-quantum well structure, the active layer MQW may have a structure in which a plurality of well layers and barrier layers are alternately stacked. In this case, the well layer may be formed of InGaN, and the barrier layer may be formed of GaN or AlGaN, but is not limited thereto. In an embodiment, a thickness of the well layer may be approximately 1 to 4 nm, and a thickness of the barrier layer may be approximately 3 to 10 nm.

In another embodiment, the active layer MQW may have a structure in which semiconductor materials having a high energy band gap and semiconductor materials having a low energy band gap are alternately stacked with each other, and may include other III to V group semiconductor materials according to a wavelength range of emitted light. Light emitted from the active layer MQW is not limited to the first light (light in the blue wavelength band) and may be second light (light in the green wavelength band) or third light (light in the red wavelength band) in some cases. In an embodiment, a thickness Tmqw of the active layer MQW may be approximately 10 nm to 25 nm.

The superlattice layer SLT may be disposed on the active layer MQW. The superlattice layer SLT may be a layer for relieving stress between the second semiconductor layer SEM2 and the active layer MQW. For example, the superlattice layer SLT may be formed of InGaN or GaN. In an embodiment, a thickness Tslt of the superlattice layer SLT may be approximately 50 to 200 nm. However, in an embodiment, the superlattice layer SLT may be omitted.

The second semiconductor layer SEM2 may be disposed on the superlattice layer SLT. The second semiconductor layer SEM2 may be doped with a second conductivity type dopant, such as Si, Se, Ge, or Sn. For example, the second semiconductor layer SEM2 may be n-GaN doped with n-type Si. In an embodiment, a thickness Tsem2 of the second semiconductor layer SEM2 may be approximately 500 nm to 1 μm.

In an embodiment, the light emitting element LE may further include an element reflective layer RFO, an insulating layer INS, and a pad connection electrode PCE.

The element reflective layer RFO may be disposed on a bottom surface of the first semiconductor layer SEM1. In an embodiment, the element reflective layer RFO may be in direct contact with the first semiconductor layer SEM1. The element reflective layer RFO reflects light emitted from the active layer MQW of the light emitting element LE toward the element reflective layer RFO to improve the light emission efficiency of the light emitting element LE.

The insulating layer INS may be disposed on a side surface of each light emitting element LE and a bottom surface of the light emitting element LE. The insulating layer INS may not be disposed on the top surface of each light emitting element LE. The insulating layer INS may be disposed on the bottom surface of the element reflective layer RFO. The insulating layer INS may include an opening OP. The insulating layer INS may expose the element reflective layer RFO through the opening OP.

The pad connection electrode PCE may be disposed on the bottom of the insulating layer INS disposed on the bottom of the light emitting element LE. The pad connection electrode PCE is disposed to cover the opening OP of the insulating layer INS and may contact the element reflective layer RFO exposed through the opening OP. A side of the pad connection electrode PCE may be disposed on a straight line with a side of the light emitting element LE. The insulating layer INS may be formed of an inorganic film, such as silicon oxide (SiO₂), aluminum oxide (Al₂O₃), or hafnium oxide (HfOₓ) but is not limited thereto.

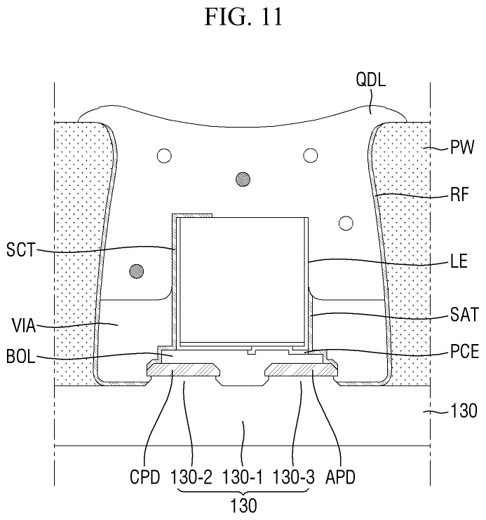

FIG. 11 is an enlarged view schematically illustrating a first light emitting region according to another embodiment, corresponding to the region of FIG. 7.

The embodiment of FIG. 11 differs from the embodiments of FIGS. 6 to 10 above in that the organic pattern layer BOL protrudes outwardly from a side of the light emitting element LE. Herein, descriptions overlapping with the above-described embodiment may be omitted and differences will be described.

Referring to FIG. 11, a width of the organic pattern layer BOL may be wider than the width of the light emitting element LE. Accordingly, a side surface of the organic pattern layer BOL may protrude outward from the light emitting element LE. Further, the organic pattern layer BOL may be disposed inwardly from the outer edges of the first pad electrode CPD and the second pad electrode APD. When viewed from a side, the light emitting element LE, the organic pattern layer BOL, and the first pad electrode CPD (or the second pad electrode APD) may have a step shape with a step difference from each other.

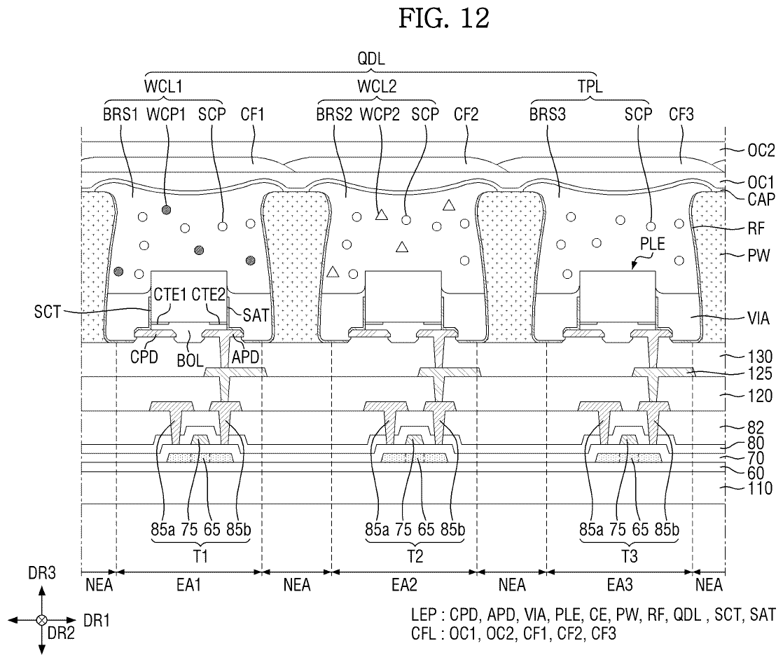

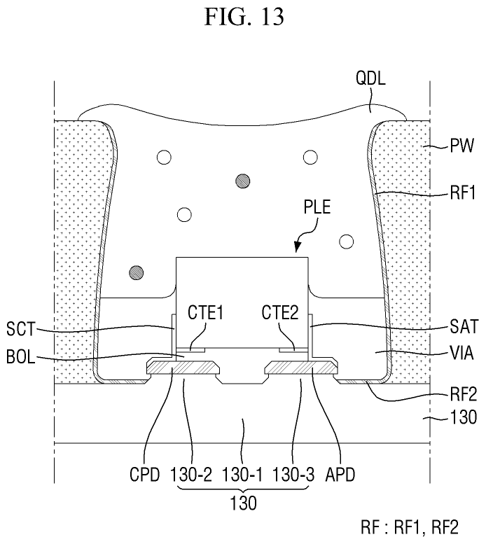

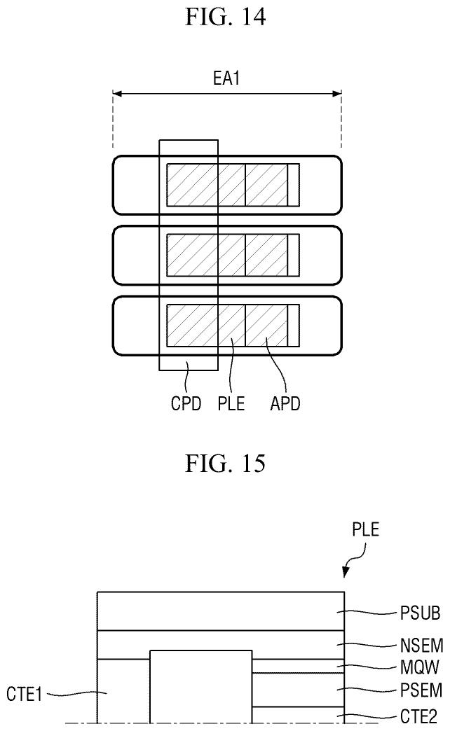

FIG. 12 is a cross-sectional view schematically illustrating a display device according to another embodiment. FIG. 13 is an enlarged view schematically illustrating a first light emitting area described with reference to FIG. 12. FIG. 14 is a plan view of the light emitting area explained with reference to FIG. 13. FIG. 15 is an enlarged view of a light emitting element included in FIG. 13.

The embodiments of FIGS. 12 to 15 differ from the embodiments of FIGS. 6 to 10 in that the light emitting element LE is a flip-chip type. Herein, descriptions overlapping with the above-described embodiment may be omitted and differences will be described.

Referring to FIGS. 12 to 15, the light emitting element part LEP may be disposed on the second planarization layer 130. The light emitting element part LEP may include a first pad electrode CPD, a second pad electrode APD, an organic pattern layer BOL, a light emitting element LE, a first auxiliary connection electrode SCT, a second auxiliary connection electrode SAT, a partition wall PW, a reflective layer RF, a via layer VIA, a flip-chip type light emitting element PLE and a wavelength conversion layer QDL.

A flip-chip type light emitting element PLE may include a first contact electrode CTE1 and a second contact electrode CTE2. In an embodiment, the first contact electrode CTE1 and the second contact electrode CTE2 are electrodes disposed to be corresponding to the first pad electrode CPD and the second pad electrode APD, and the flip-chip type light emitting element PLE may be flip-chip type micro-LED.

The flip-chip type light emitting element PLE may be an inorganic light emitting element made of an inorganic material, such as GaN. In an embodiment, the flip-chip type light emitting element PLE may have a length in the first direction DR1, a length in the second direction DR2, and a length in the third direction DR3 of several to hundreds of μm, respectively. For example, the flip-chip type light emitting element PLE may have dimensions of 10 μm×25 μm, but is not limited thereto.

The flip-chip type light emitting element PLE may be a light emitting structure including a base substrate PSUB, an n-type semiconductor NSEM, the active layer MQW, a p-type semiconductor PSEM, the first contact electrode CTE1, and the second contact electrode CTE2.

In an embodiment, the base substrate PSUB of the flip-chip type light emitting element PLE may be a sapphire substrate, but is not limited thereto.

The n-type semiconductor NSEM of the flip-chip type light emitting element PLE may be disposed on a surface of the base substrate PSUB. For example, the n-type semiconductor NSEM may be disposed on a bottom surface of the base substrate PSUB. The n-type semiconductor NSEM may be made of GaN doped with an n-type conductive dopant, such as Si, Ge, or Sn. The n-type semiconductor NSEM corresponds to the second semiconductor layer SEM2 of the light emitting element LE described with reference to FIGS. 6 to 10.

The active layer MQW of the flip-chip type light emitting element PLE may be disposed on a portion of a surface of the n-type semiconductor NSEM. The active layer MQW may include a material with a single or multiple quantum well structure. In an embodiment, the active layer MQW includes a material with a multi-quantum well structure, and may have a structure in which a plurality of well layers and barrier layers are alternately stacked. In this case, the well layer may be formed of InGaN, and the barrier layer may be formed of GaN or AlGaN, but are not limited thereto.

In another embodiment, the active layer MQW may be a structure in which semiconductor materials with a large energy band gap and semiconductor materials with a low energy band gap are alternately stacked or may include other III to V group semiconductor materials, depending on a wavelength of the light to be emitted.

The p-type semiconductor PSEM may be disposed on a surface of the active layer MQW. The p-type semiconductor PSEM may be made of GaN doped with a p-type conductive dopant, such as Mg, Zn, Ca, Sr, Ba, and the like. The p-type semiconductor PSEM corresponds to the first semiconductor layer SEM1 of the light emitting element LE described with reference to FIGS. 6 to 10.

The second contact electrode CTE2 may be disposed on a surface of the p-type semiconductor PSEM, and the first contact electrode CTE1 may be disposed on another part of a surface of the n-type semiconductor NSEM. The first contact electrode CTE1 and the second contact electrode CTE2 do not directly contact each other. Another part of a surface of the n-type semiconductor NSEM on which the first contact electrode CTE1 is disposed may be disposed away from a part of a surface of the n-type semiconductor NSEM on which the active layer MQW is disposed.

The first auxiliary connection electrode SCT is disposed along a side of the flip-chip type light emitting element PLE and connects the first contact electrode CTE1 and the first pad electrode CPD. The first auxiliary connection electrode SCT includes a conductive material and may directly contact the first contact electrode CTE1 and the first pad electrode CPD.

An end of the first auxiliary connection electrode SCT is disposed on a side of the flip-chip type light emitting element PLE, and another end of the first auxiliary connection electrode SCT is disposed on a side of the first pad electrode CPD.

That is, the first auxiliary connection electrode SCT extends from the side of the light emitting element LE, along the side of the first contact electrode CTE1 and along the side of the organic pattern layer BOL and is disposed along at least a portion of the top surface and side of the first pad electrode CPD.

The second auxiliary connection electrode SAT is disposed along the side of the light emitting element LE and may extend along the side of the second contact electrode CTE2, the side of the organic pattern layer BOL, and the top surface and the side of the second pad electrode APD. The second auxiliary connection electrode SAT connects the second contact electrode CTE2 of the light emitting element LE and the second pad electrode APD. In an embodiment, the second auxiliary connection electrode SAT includes a conductive material and directly contacts the second contact electrode CTE2 and the second pad electrode APD.

In an embodiment, heights of the first auxiliary connection electrode SCT and the second auxiliary connection electrode SAT may be the same as a height of the via layer VIA, or may be lower than the height of the via layer VIA.

As will be described later, the first auxiliary connection electrode SCT and the second auxiliary connection electrode SAT may be formed through a same process as the reflective layer RF disposed on the side of the partition wall PW. Accordingly, the first auxiliary connection electrode SCT and the second auxiliary connection electrode SAT may include a same material as the reflective layer RF. For example, the first auxiliary connection electrode SCT and the second auxiliary connection electrode SAT may include aluminum or silver, which are metallic materials that are highly reflective of light, or may include alloys thereof.

The reflective layer RF may include the first reflective layer RF1 around (e.g., surrounding) the side of the partition wall PW and the second reflective layer RF2 disposed on a flat surface between the partition wall PW and the light emitting element LE. In an embodiment, the first reflective layer RF1 and the second reflective layer RF2 may be continuously connected.

The flip-chip type light emitting elements PLE may be formed by growing on a semiconductor substrate, such as a silicon wafer. In an embodiment, each of the flip-chip type light emitting elements PLE may be directly transferred from the silicon wafer onto the first pad electrode CPD and the second pad electrode APD of the substrate 110. In another embodiment, each of the flip-chip type light emitting elements PLE may be transferred onto the first pad electrode CPD and the second pad electrode APD of the substrate 110 by an electrostatic method using an electrostatic head or by a stamping method using an elastic polymeric material, such as PDMS or silicone, as a transfer substrate.

In an embodiment, the first contact electrode CTE1, the first pad electrode CPD, and the second contact electrode CTE2 and the second pad electrode APD may be bonded to each other through a conductive adhesive member, such as an anisotropic conductive film (ACF) or an anisotropic conductive paste (ACP). In another embodiment, the first contact electrode CTE1 and the first pad electrode CPD may be bonded to each other through a soldering process.

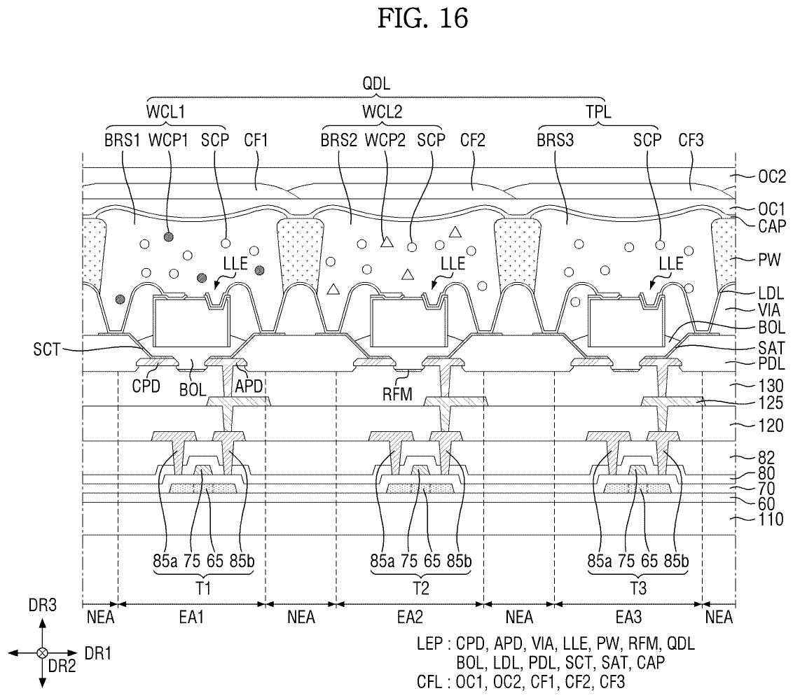

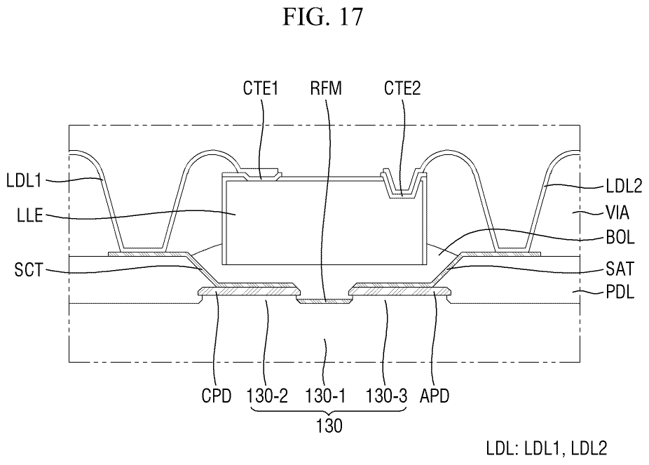

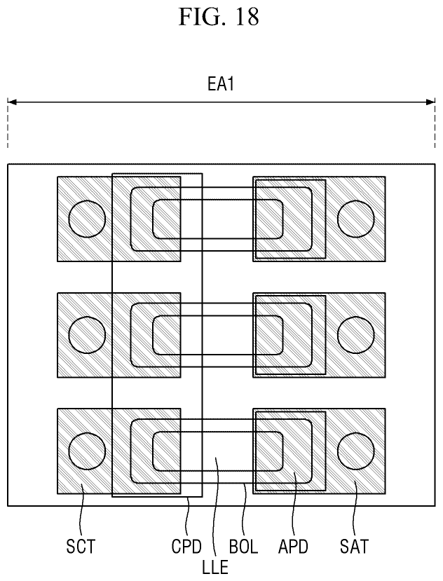

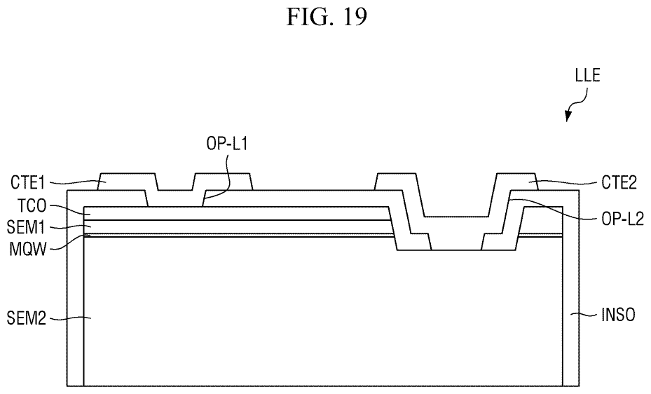

FIG. 16 is a cross-sectional view schematically illustrating a display device according to another embodiment. FIG. 17 is an enlarged view schematically illustrating a first light emitting area described with reference to FIG. 16. FIG. 18 is a plan view of the light emitting area explained with reference to FIG. 16. FIG. 19 is an enlarged view of a light emitting element included in FIG. 17.

The embodiments of FIGS. 16 to 19 differ from the embodiments of FIGS. 6 to 10 in that the light emitting element is of a lateral type. Herein, descriptions overlapping with the above-described embodiment may be omitted and differences will be described.

Referring to FIGS. 16 to 19, the light emitting element part LEP may be disposed on the second planarization layer 130. The light emitting element part LEP may include a first pad electrode CPD, a second pad electrode APD, a bank PDL, an organic pattern layer BOL, a lateral light emitting element LLE, a first auxiliary connection electrode SCT, a second auxiliary connection electrode SAT, a horizontal reflective layer RFM, a via layer VIA, a partition wall PW, and a wavelength conversion layer QDL.

The second planarization layer 130 may have an undercut structure in a portion overlapping the first pad electrode CPD and the second pad electrode APD. For example, the second planarization layer 130 includes the first planarization part 130-1 disposed on the substrate 110, the second planarization part 130-2 disposed on the first planarization portion 130-1, and the third planarization part 130-3 disposed on the first planarization portion 130-1. In an embodiment, the second planarization part 130-2 and the third planarization part 130-3 may be arranged to be spaced apart from each other on a same plane. The second planarization part 130-2 may overlap the first pad electrode CPD, and the third planarization part 130-3 may overlap the second pad electrode APD.

The first pad electrode CPD, the second pad electrode APD, and the bank PDL may be formed on the second planarization layer 130. For example, the first pad electrode CPD may be disposed on the second planarization part 130-2, and the second pad electrode APD may be disposed on the third planarization part 130-3. The first pad electrode CPD and the second pad electrode APD may be arranged to be spaced apart from each other.

The bank PDL may be formed to cover a portion of the first pad electrode CPD and the second pad electrode APD. The bank PDL may be formed to cover edges of the first pad electrode CPD and the second pad electrode APD. In an embodiment, the bank PDL may include an inclined part that overlaps the edges of the first pad electrode CPD and the second pad electrode APD and has a slope (e.g., a predetermined slope), and a flat part that extends from the inclined part and has a flat plane.

The first auxiliary connection electrode SCT and the second auxiliary connection electrode SAT may be disposed on the first pad electrode CPD and the second pad electrode APD, respectively. For example, the first auxiliary connection electrode SCT may be disposed on the first pad electrode CPD, and the second auxiliary connection electrode SAT may be disposed on the second pad electrode APD. The first auxiliary connection electrode SCT and the second auxiliary connection electrode SAT may be disposed to be spaced apart from each other, and each of the first auxiliary connection electrode SCT and the second auxiliary connection electrode SAT may be disposed on a top surface of the bank PDL along the bank PDL. An end of each of the first auxiliary connection electrode SCT and the second auxiliary connection electrode SAT may be disposed on a flat part of the bank PDL.

The horizontal reflective layer RFM may be disposed on the first planarization part 130-1 between the second planarization part 130-2 and the third planarization part 130-3. In an embodiment, the horizontal reflective layer RFM includes a same material as the first auxiliary connection electrode SCT and the second auxiliary connection electrode SAT. The horizontal reflective layer RFM may be disposed between the first auxiliary connection electrode SCT and the second auxiliary connection electrode SAT and may be disconnected from the first auxiliary connecting electrode SCT and the second auxiliary connecting electrode SAT by an undercut shape of the second planarization layer 130.

The organic pattern layer BOL may be disposed to cover a portion of the first auxiliary connection electrode SCT and the second auxiliary connection electrode SAT and the horizontal reflective layer RFM.

The lateral light emitting element LLE is disposed on the organic pattern layer BOL.

The lateral light emitting element LLE may include the first contact electrode CTE1 and the second contact electrode CTE2. In an embodiment, as an example, the first contact electrode CTE1 and the second contact electrode CTE2 may be disposed on the top surface of the lateral light emitting element LLE and the lateral light emitting element LLE may be lateral chip type micro LED.

In an embodiment, the lateral light emitting element LLE may be an inorganic light emitting element made of an inorganic material, such as GaN. The lateral light emitting element LLE may have a length in the first direction DR1, a length in the second direction DR2, and a length in the third direction DR3 of several to hundreds of μm, respectively. For example, the lateral light emitting element LLE may have dimensions of 10 μm×25 μm, but is not limited thereto.

The lateral light emitting element LLE may be a light emitting structure including the second semiconductor layer SEM2, the active layer MQW, the first semiconductor layer SEM1, the first contact electrode CTE1, and the second contact electrode CTE2.

The second semiconductor layer SEM2, the active layer MQW, and the first semiconductor layer SEM1 of the lateral light emitting element LLE correspond to the second semiconductor layer SEM2, the active layer MQW, and the first semiconductor layer SEM1 of the light emitting element LE described with reference to FIG. 10, and, as such, a redundant description will be omitted. The lateral light emitting element LLE may further include a transparent conductive layer TCO on the first semiconductor layer SEM1. The transparent conductive layer TCO may be formed to be transparent to emit light. The transparent conductive layer TCO may be formed of a transparent conductive oxide, such as any of indium tin oxide (ITO) and indium zinc oxide (IZO).

The lateral light emitting element LLE further includes an element insulating layer INSO. The element insulating layer INSO may be formed around (e.g., to surround) the side surfaces of the second semiconductor layer SEM2, the active layer MQW, the first semiconductor layer SEM1, and the transparent conductive layer TCO and the top surface of the transparent conductive layer TCO. In an embodiment, the element insulating layer INSO has two openings. For example, the element insulating layer INSO includes a first opening OP-L1 and a second opening OP-L2.

The first contact electrode CTE1 and the second contact electrode CTE2 are disposed in the two openings. For example, the first contact electrode CTE1 may be disposed in the first opening OP-L1 and contact the first semiconductor layer SEM1. The second contact electrode CTE2 may be disposed in the second opening OP-L2 and contact the second semiconductor layer SEM2. The lateral light emitting element LLE may further include a recess that overlaps the second opening OP-L2. The second semiconductor layer SEM2 may be exposed by the recess. In an embodiment, the second opening OP-L2 may have a wider diameter than the first opening OP-L1.

The element insulating layer INSO may be disposed to cover the side surface of the recess that overlaps the second opening OP-L2. The first contact electrode CTE1 and the second contact electrode CTE2 may be formed of a transparent conductive oxide, such as any of indium tin oxide (ITO) and indium zinc oxide (IZO).

The via layer VIA may be disposed to support a lead line LDL connecting the first contact electrode CTE1 and the second contact electrode CTE2 with the first auxiliary connection electrode SCT and the second auxiliary connection electrode SAT.

The lead line LDL may be included in the light emitting element part LEP, and may include a first lead line LDL1 connecting the first contact electrode CTE1 with the first auxiliary connection electrode SCT, and a second lead line LDL2 connecting the second contact electrode CTE2 with the second auxiliary connection electrode SAT.

The first semiconductor layer SEM1, the first contact electrode CTE1, the first lead line LDL1, the first auxiliary connection electrode SCT, and the first pad electrode CPD may be electrically connected, and the second semiconductor layer SEM2, the second contact electrode CTE2, the second lead line LDL2, the second auxiliary connection electrode SAT, and the second pad electrode APD may be electrically connected.

A shape of the via layer VIA is not limited, as long as it can support the lead line LDL.

The partition wall PW may be formed on the via layer VIA. The partition wall PW overlaps the bank PDL and does not overlap the lateral light emitting element LLE. The wavelength conversion layer QDL may be disposed in the space formed by the partition wall PW.

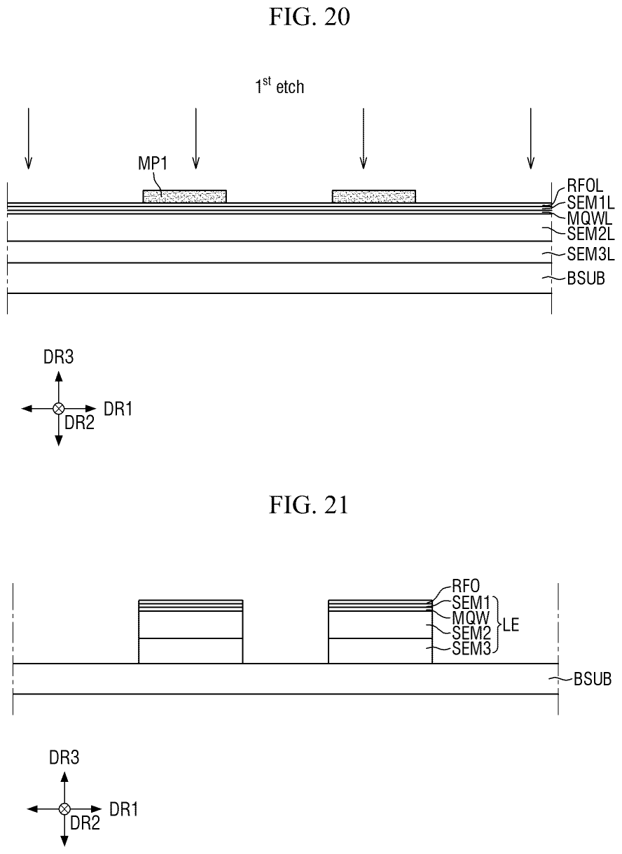

FIGS. 20 to 38 are diagrams to illustrate a method of manufacturing a display device according to an embodiment.

FIGS. 20 to 38 illustrate a structure of each layer of the display device 10 in the order of formation, respectively, in cross-sectional view. FIGS. 20 to 38 illustrate a manufacturing process of the light emitting element part LEP, which may roughly correspond to the cross-sectional views of FIGS. 6 to 8 and FIG. 10. Also, the first light emitting area EA1 of the display device 10 is described below.

Referring to FIGS. 20 to 24, a plurality of light emitting elements LE are formed on a base substrate BSUB.

In an embodiment, the base substrate BSUB is prepared. The base substrate BSUB may be a sapphire substrate of Al₂O₃ or a silicon wafer including silicon. However, the present disclosure is not limited thereto, and, in an embodiment, a case in which the base substrate BSUB is a sapphire substrate will be described as an example.

A plurality of semiconductor material layers SEM3L, SEM2L, MQWL, and SEM1L are formed on the base substrate BSUB. In an embodiment, the plurality of semiconductor material layers SEM3L, SEM2L, MQWL, and SEM1L grown by an epitaxial method may be formed by growing a seed crystal. Methods for forming semiconductor material layers SEM3L, SEM2L, MQWL, and SEM1L include electron beam deposition, physical vapor deposition (PVD), chemical vapor deposition (CVD), and plasma laser deposition (PLD), dual-type thermal evaporation, sputtering, metal organic chemical vapor deposition (MOCVD), and the like, and, in an embodiment, the semiconductor material layers SEM3L, SEM2L, MQWL, and SEM1L are formed by metal organic chemical vapor deposition (MOCVD). However, the present disclosure is not limited thereto.

A precursor material for forming the plurality of semiconductor material layers SEM3L, SEM2L, MQWL, and SEM1L is not particularly limited within the range that may be conventionally selected for forming the subject material. In an example, the precursor material may be a metal precursor including an alkyl group, such as a methyl or ethyl group. For example, the precursor material may be a compound such as trimethyl gallium (Ga(CH₃)₃), trimethyl aluminum (Al(CH₃)₃), triethyl phosphate ((C₂H₅)₃PO₄), but is not limited thereto.

In an embodiment, a third semiconductor material layer SEM3L is formed on the base substrate BSUB. While the drawings illustrate a single layer of the third semiconductor material layer SEM3L, the present disclosure is not limited thereto, and the third semiconductor material layer SEM3L may be formed to be a plurality of layers. The third semiconductor material layer SEM3L may be disposed to reduce a lattice constant difference between a second semiconductor material layer SEM2L and the base substrate BSUB. For example, the third semiconductor material layer SEM3L may include an undoped semiconductor, which may be an n-type or p-type undoped material. In an embodiment, the third semiconductor material layer SEM3L may be at least one of undoped InAlGaN, GaN, AlGaN, InGaN, AlN, and InN, but is not limited thereto.

In an embodiment, the second semiconductor material layer SEM2L, the active material layer MQWL, and the first semiconductor material layer SEM1L are sequentially formed on the third semiconductor material layer SEM3L by using the above-described method.

Next, a reflective material layer RFOL is formed on the plurality of semiconductor material layers SEM3L, SEM2L, MQWL, and SEM1L. The reflective material layer RFOL may be formed to cover all the plurality of semiconductor material layers SEM3L, SEM2L, MQWL, and SEM1L. In an embodiment, the reflective material layer RFOL may include aluminum (Al) or silver (Ag) or may be an alloy thereof.

Then, the plurality of semiconductor material layers SEM3L, SEM2L, MQWL, and SEM1L and the reflective material layers RFOL are etched.

In an embodiment, a plurality of first mask patterns MP1 are formed on the reflective material layer RFOL. The first mask pattern MP1 may be a hard mask including an inorganic material or a photoresist mask including an organic material. The first mask pattern MP1 prevents or substantially prevents the lower plurality of semiconductor material layers SEM3L, SEM2L, MQWL, and SEM1L and the reflective material layer RFOL from being etched. Next, a portion of the plurality of semiconductor material layers SEM3L, SEM2L, MQWL, SEM1L and the reflective material layer RFOL are etched (1^{st} etch) using the plurality of first mask patterns MP1 as a mask.

As shown in FIG. 21, on the base substrate BSUB, portions of the plurality of semiconductor material layers SEM3L, SEM2L, MQWL, and SEM1L and the reflective material layer RFOL that are non-overlapping with the first mask pattern MP1 are etched and removed, and portions of the plurality of semiconductor material layers SEM3L, SEM2L, MQWL, and SEM1L and the reflective material layer RFOL that are overlapped with the first mask pattern MP1 and are not etched may be formed into the plurality of light emitting elements LE.

The plurality of semiconductor material layers SEM3L, SEM2L, MQWL, and SEM1L and the reflective material layer RFOL may be etched by conventional methods. For example, the process of etching the plurality of semiconductor material layers SEM3L, SEM2L, MQWL, and SEM1L and the reflective material layer RFOL may be performed by any of dry etching, wet etching, reactive ion etching (RIE), deep reactive ion etching (DRIE), inductively coupled plasma reactive ion etching (ICP-RIE), and the like. In the case of dry etching methods, anisotropic etching is possible, which may be suitable for vertical etching. When utilizing the etching method described above, the etchant may be Cl₂ or O₂. However, the present disclosure is not limited thereto.

Portions of the plurality of semiconductor material layers SEM3L, SEM2L, MQWL, and SEM1L and the reflective material layer RFOL overlapping the first mask pattern MP1 are not etched but are formed into the plurality of light emitting elements LE and an element reflective layer RFO. Thus, the plurality of light emitting elements LE including the third semiconductor layer SEM3, the second semiconductor layer SEM2, the active layer MQW, and the first semiconductor layer SEM1 are formed.

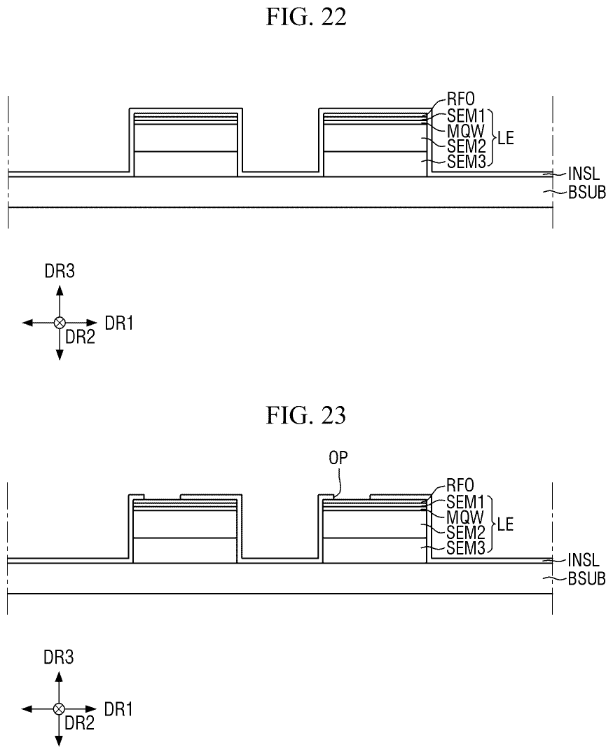

Next, referring to FIGS. 22 and 23, an insulating material layer INSL having an opening OP is formed on the base substrate BSUB on which the light emitting element LE is formed.

The insulating material layer INSL is formed on outer surfaces of the plurality of light emitting elements LE. In an embodiment, the insulating material layer INSL may be formed on the entire surface of the base substrate BSUB and may be formed not only on the light emitting element LE, but also on the top surface of the base substrate BSUB exposed by the light emitting element LE.

Then, a second etch is performed to partially remove the insulating material layer INSL to form an insulating material layer INSL having an opening OP on a top surface of the light emitting element LE.

The second etch may be performed in which the insulating material layer INSL is partially removed such that the insulating material layer INSL exposes the top surface of the light emitting element LE but surrounds sides of the light emitting element LE. In this process, a portion of the insulating material layer INSL may be removed to expose at least a portion of the top surface of the element reflective layer RFO of the light emitting element LE. The process of partially removing the insulating material layer INSL may be performed by a mask process.

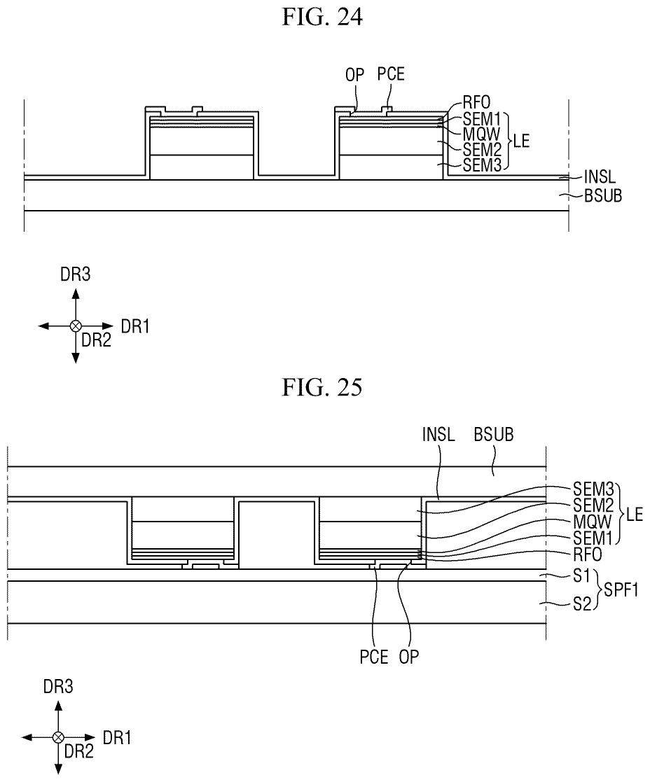

Referring to FIG. 24, the light emitting element LE may be formed by forming the pad connection electrode PCE on the light emitting element LE.

For example, the pad connection electrode PCE covering the opening OP of the light emitting element LE is formed by stacking a pad connection electrode material layer on the base substrate BSUB and then etching it through an etching process. The pad connection electrode material layer is formed of a conductive material and may include at least one of gold (Au), copper (Cu), tin (Sn), silver (Ag), aluminum (AI), and titanium (Ti). For example, the pad connection electrode material layer may include a 9:1 alloy, an 8:2 alloy, or a 7:3 alloy of gold and tin, or may include an alloy of copper, silver, and tin (SAC305).

Next, referring to FIG. 25, a support film SPF1 is attached to the plurality of light emitting elements LE on the base substrate BSUB prepared in FIG. 24.

Specifically, the support film SPF1 is attached on the plurality of light emitting elements LE. The support film SPF1 may be aligned on the plurality of light emitting elements LE and attached to each pad connection electrode PCE of the plurality of light emitting elements LE. The plurality of light emitting elements LE may be arranged in a large number so as to be attached to the support film SPF1 without being detached.

In an embodiment, the support film SPF1 may be composed of a support layer S2 and an adhesive layer S1 disposed on the support layer S2. The support layer S2 may be made of a material that is transparent and mechanically stable to allow light to pass through. For example, the support layer S2 may include a transparent polymer, such as polyester, polyacrylic, polyepoxy, polyethylene, polystyrene, polyethylene terephthalate, or the like. The adhesive layer S1 may include an adhesive material for adhering the light emitting element LE. For example, the adhesive material may include any of urethane acrylate, epoxy acrylate, polyester acrylate, and the like. The adhesive material may be a material of which an adhesive strength changes as ultraviolet rays (UV) or heat are applied, and, thus, the adhesive layer S1 may be easily separated from the light emitting element LE.

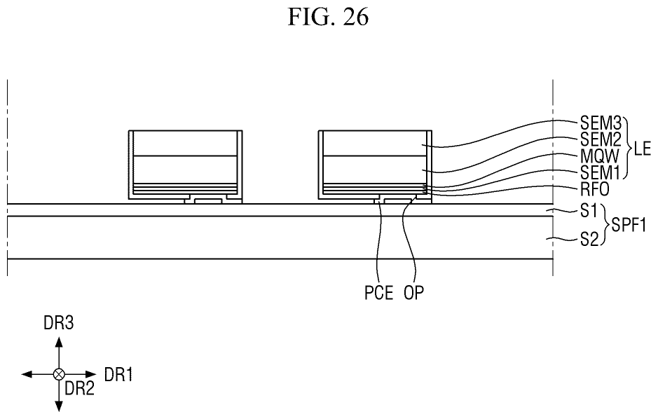

Next, referring to FIG. 26, a laser (1^{st} laser) is irradiated to the base substrate BSUB to separate the light emitting elements LE from the base substrate BSUB. The base substrate BSUB is separated from each third semiconductor layer SEM3 of the plurality of light emitting elements LE.

The process of separating the base substrate BSUB may be performed using a laser lift off (LLO) process. The laser lift-off process uses a laser, and, in an embodiment, a KrF excimer laser (248 nm wavelength) may be used as the light source. In an embodiment, an energy density of the excimer laser is irradiated in the range of about 550 mJ/cm² to 950 mJ/cm², and an incident area may be in a range of 50×50 μm² to 1×1 cm², but is not limited thereto. By irradiating the laser to the base substrate BSUB, the base substrate BSUB may be separated from the light emitting element LE.

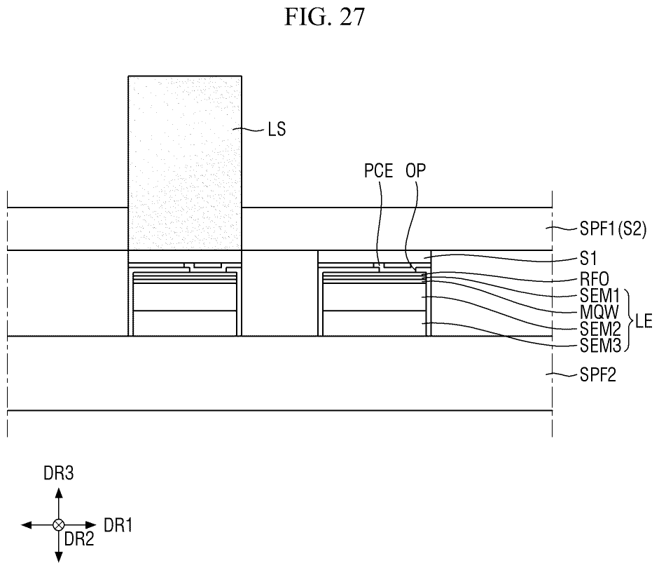

Next, referring to FIG. 27, a relay substrate SPF2 is attached to the plurality of light emitting elements LE separated from the base substrate BSUB.

The plurality of light emitting elements LE disposed on the support film SPF1 are aligned on the relay substrate SPF2, and a laser LS is irradiated on the support film SPF1. The light emitting element LE irradiated with the laser LS may be separated from the support film SPF1 and transferred onto the relay substrate SPF2. The relay substrate SPF2 may include a support layer and an adhesive layer, such as the support film SPF1 described above, to bond and support the plurality of light emitting elements LE.

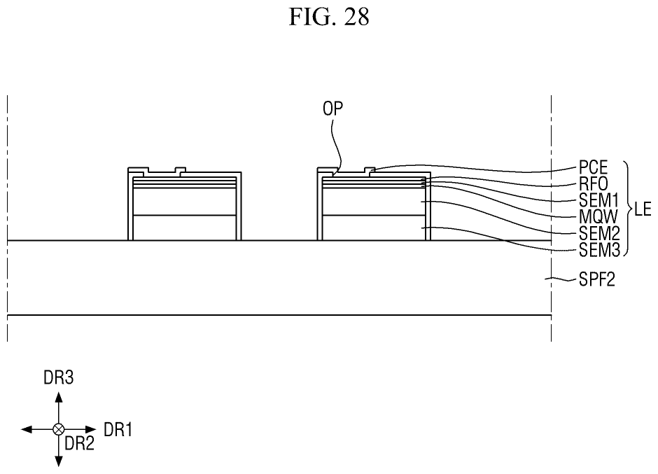

Next, referring to FIG. 28, the support film SPF1 is separated from the plurality of light emitting elements LE. By laser LS irradiation, the adhesive strength of the adhesive layer S1 of the support film SPF1 may be reduced, and the support film SPF1 can be physically or naturally separated.

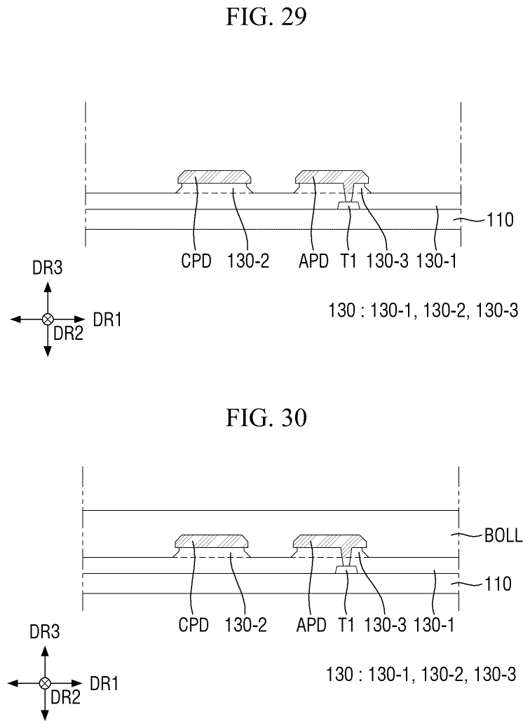

Next, referring to FIG. 29, a second planarization layer 130 having an undercut-shaped structure is formed.

Specifically, a substrate 110 is prepared. As described with reference to FIG. 6, the substrate 110 may be a substrate on which the second planarization layer 130, the first pad electrode CPD, and the second pad electrode APD are formed.

The second planarization layer 130 may include a first planarization part 130-1 disposed on the substrate 110, and a second planarization part 130-2 and a third planarization part 130-3 formed on the first planarization part 130-1.

A side surface of the second planarization part 130-2 is etched to have an undercut structure recessed towards a center portion of the first pad electrode CPD form a side surface thereof. Also, a side surface of the third planarization part 130-3 is etched to have an undercut structure recessed towards a center portion of the second pad electrode APD from a side surface thereof. For example, an etching process is performed by supplying an etchant to the second planarization layer 130. The second planarization part 130-2 and the third planarization part 130-3 to which the etchant is applied are selectively etched. In an embodiment, the etchant process time includes not only a first process time to completely remove a portion of the second planarization layer 130 which is not in a region overlapped with the first pad electrode CPD and the second pad electrode APD and is located in the same level with the second planarization part 130-2 and the third planarization part 130-3, but also a second process time to form an undercut structure of the second planarization part 130-2 and the third planarization part 130-3 in a region overlapped with the first pad electrode CPD and the second pad electrode APD. For example, if the first process time is about 60 seconds and the second process time is α seconds, the etchant process proceeds for a time of (60 seconds+α seconds).

After the first process time, a portion of the second planarization layer 130 which is not in a region overlapped with the first pad electrode CPD and the second pad electrode APD and is located in the same level with the second planarization part 130-2 and the third planarization part 130-3 are removed to expose the first planarization part 130-1, and the sides of the second planarization part 130-2 and the third planarization part 130-3 in the region overlapping the first pad electrode CPD and the second pad electrode APD are exposed. After the second process time, the sides of the second planarization part 130-2 and the third planarization part 130-3 have an undercut-shape with an inward depression.

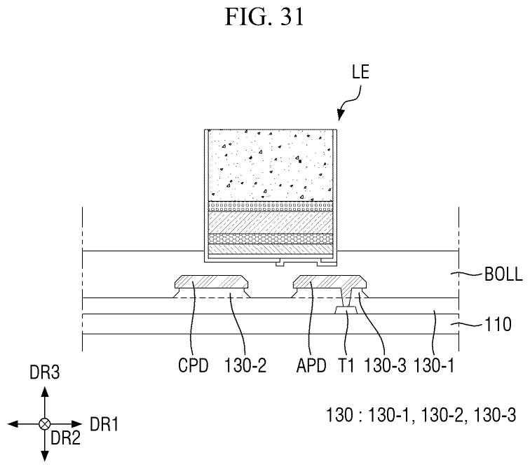

Thereafter, referring to FIGS. 30 and 31, a plurality of light emitting elements LE arranged on a relay substrate SPF2 are transferred to the substrate 110.

In an embodiment, an organic pattern material layer BOLL is entirely applied on the second planarization layer 130 on which the first pad electrode CPD and the second pad electrode APD are disposed. In an embodiment, the organic pattern material layer BOLL may be applied to a thickness of about 2 μm, but is not limited thereto. At this stage, the organic pattern material layer BOLL is not hardened and is in a fluid state, which may be referred to as a pseudo-adhesive layer.

Next, the relay substrate SPF2 is aligned on the substrate 110. The pad connection electrode PCE of the light emitting element LE grown on the relay substrate SPF2 is aligned to be disposed on the second pad electrode APD of the substrate 110 with the organic pattern material layer BOLL interposed therebetween.

Next, the substrate 110 and the relay substrate SPF2 are bonded. The pad connection electrode PCE of the light emitting element LE to which the relay substrate SPF2 is attached and is in contact with the organic pattern material layer BOLL. Next, heat and pressure are applied to the organic pattern material layer BOLL to cure the organic pattern material layer BOLL. As a result, the light emitting element LE and the organic pattern material layer BOLL may be bonded. As such, the heat and pressure of the process of curing the organic pattern material layer BOLL to bond the light emitting element LE is lower than the heat and pressure of a eutectic bonding process. For example, while the eutectic bonding process is a relatively high temperature process of about 200 to 400 degrees Celsius, the organic material curing process may be a relatively low temperature process of 80 to 200 degrees Celsius. Accordingly, the light emitting element LE may be bonded to the substrate 110 at a relatively lower temperature and pressure compared to the eutectic bonding process.

At this time, the relay substrate SPF2 is separated from the plurality of light emitting elements LE. After applying ultraviolet rays or heat to the relay substrate SPF2 to reduce the adhesive strength of the adhesive layer of the relay substrate SPF2, the relay substrate SPF2 may be physically or naturally separated from the plurality of light emitting elements LE.

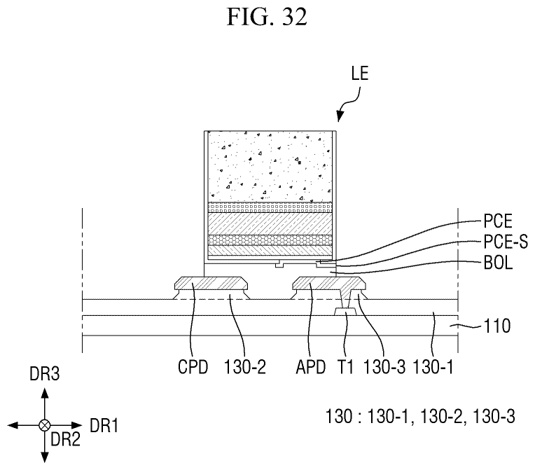

Next, referring to FIG. 32, an organic patterned layer BOL overlapping with the light emitting element LE may be formed by ashing a portion of the organic pattern material layer BOLL not overlapping with the light emitting element LE. As a portion of the organic pattern material layer BOLL not overlapping the light emitting element LE is ashed, a side PCE-S of the pad connecting electrode PCE disposed on a side of the light emitting element LE may be exposed. In an embodiment, the third semiconductor layer SEM3 of the light emitting element LE has low conductivity and may be removed, such that the second semiconductor layer SEM2 is connected to the first auxiliary connection electrode SCT. The third semiconductor layer SEM3 may be removed by a chemical polishing process, an etching process, or the like.

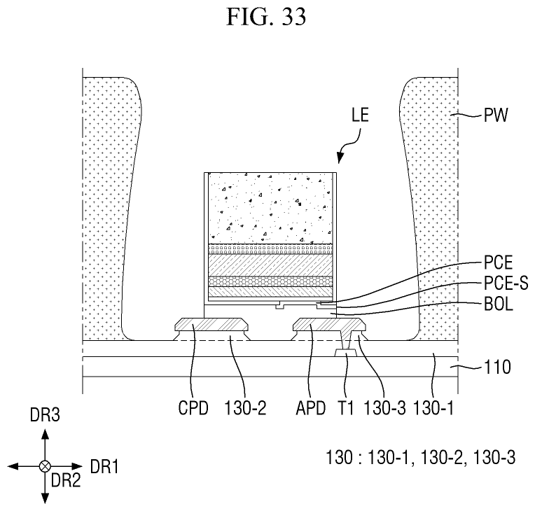

Next, referring to FIG. 33, a partition wall PW is formed on the second planarization layer 130.

In an embodiment, the partition wall PW is formed on the second planarization layer 130 using a negative photoresist. Since a portion of the negative photoresist that does not receive light is dissolved, the partition wall PW may be formed in an inverted tapered shape with a width narrowing downward.

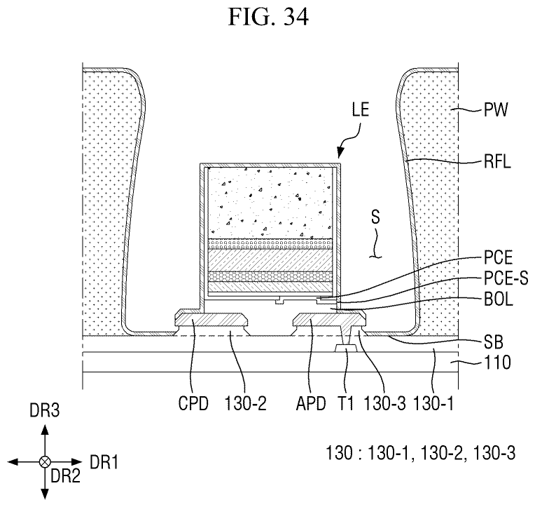

Next, referring to FIG. 34, in an embodiment, a reflective material layer RFL is deposited on the entire surface of the substrate 110 on which the partition wall PW is formed. The reflective material layer RFL may be formed to cover both the partition wall PW and the light emitting element LE.

The reflective material layer RFL is formed on a top and sides of the partition wall PW, a top and sides of the light emitting element LE, as well as on a bottom (top surface of the second planarization layer 130) between the light emitting element LE and the partition wall PW. The reflective material layer RFL is disposed along the sides of the light emitting element LE, the side PCE-S of the pad connection electrode PCE, the side of the organic pattern layer BOL, the first pad electrode CPD, and the second pad electrode APD, and is disconnected by the undercut-shaped structure of the second planarization part 130-2 and the third planarization part 130-3 of the second planarization layer 130. The reflective material layer RFL disposed along the side of the light emitting element LE, the side PCE-S of the pad connection electrode PCE, the side of the organic pattern layer BOL, the first pad electrode CPD, and the second pad electrode APD, and the reflective material layer RFL deposited on the bottom surface SB of a space S formed by the partition wall PW are discontinuously disposed. The reflective material layer RFL disposed along the side of the light emitting element LE, the side PCE-S of the pad connection electrode PCE, the side of the organic pattern layer BOL, the first pad electrode CPD, and the second pad electrode APD may be spaced apart from the reflective material layer RFL deposited on a bottom surface SB of the space S formed by the partition wall PW. The reflective material layer RFL may include, for example, aluminum (Al) or silver (Ag), or may be an alloy thereof.

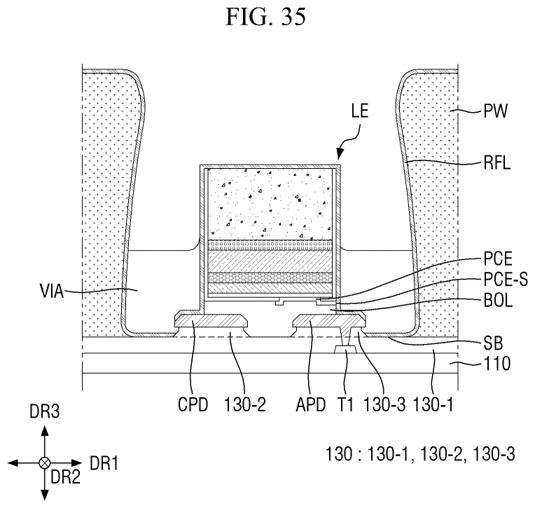

Next, referring to FIG. 35, a via layer VIA is formed in the space S formed by the partition wall PW. The via layer VIA may be applied using a solution process, such as spin coating or inkjet printing. The via layer VIA may be formed lower than a height of the light emitting element LE. For example, a top surface of the light emitting element LE may be disposed higher than the via layer VIA.

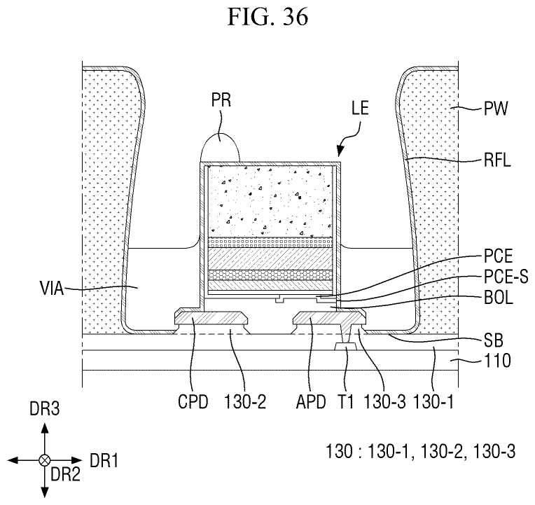

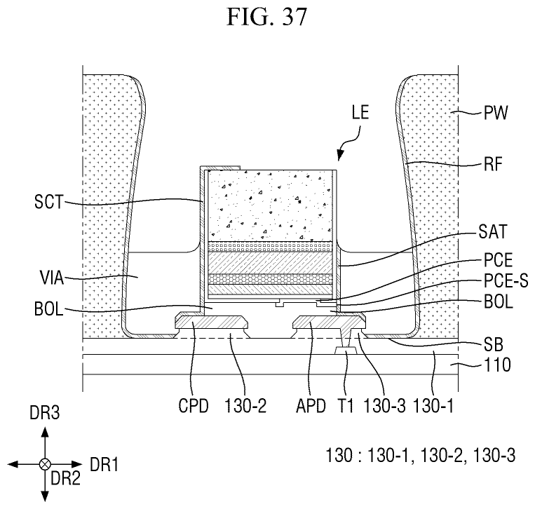

Referring to FIGS. 36 and 37, a portion of the reflective material layer RFL is removed to form a reflective layer RF on the side of the partition wall PW, and a first auxiliary connection electrode SCT and a second auxiliary connection electrode SAT are formed.

For example, referring to FIG. 36, a photoresist mask pattern PR is formed on a portion of the top surface of the light emitting element LE overlapping the first pad electrode CPD.

A second etch to partially remove the reflective material layer RFL is performed to form the reflective layer RF, the first auxiliary connection electrode SCT, and the second auxiliary connection electrode SAT.

In an embodiment, a second etch process may be performed to partially remove a portion of the reflective material layer RFL such that the reflective material layer RFL exposes the top surface of the light emitting element LE but surrounds sides of the light emitting element LE. At this time, a portion of the reflective material layer RFL overlapping the photoresist mask pattern PR, a portion of the reflective material layer RFL covered by the via layer VIA and a portion of the reflective material layer RFL located on the side surface of the partition wall PW are not etched.

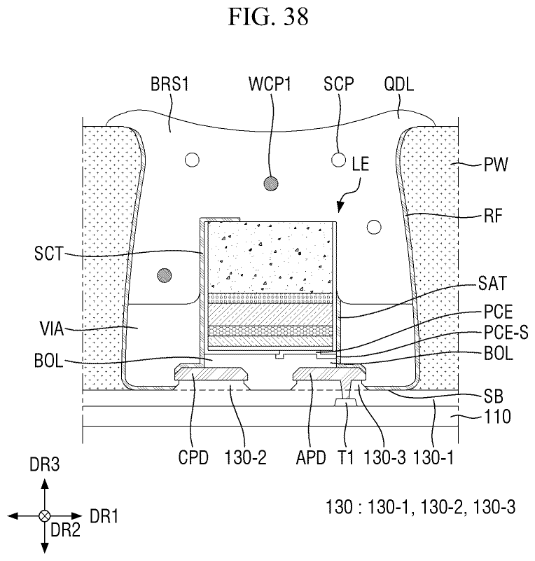

Referring to FIG. 38, a wavelength conversion layer QDL is formed in the space formed within the partition wall PW.

For example, a solution mixed with a first base resin BRS1, a first wavelength conversion particle WCP1, and a scatterer SCP may be dripped in the space formed in the partition wall PW by a solution process such as inkjet printing, imprinting, or the like but is not limited thereto. Each wavelength conversion layer QDL may be formed within a plurality of openings and may be formed to overlap a plurality of light emitting areas.

Thereafter, a capping layer CAP, a first overcoat layer OC1, a color filter, and a second overcoat layer OC2 are formed on the partition wall PW and the wavelength conversion layer QDL, as shown in FIG. 6.

In an embodiment, the color filter may be formed by a photolithography process. In an embodiment, a thickness of the color filter may be 1 μm or less, but is not limited thereto. Similarly, other color filters are formed to overlap the respective openings by a patterning process.

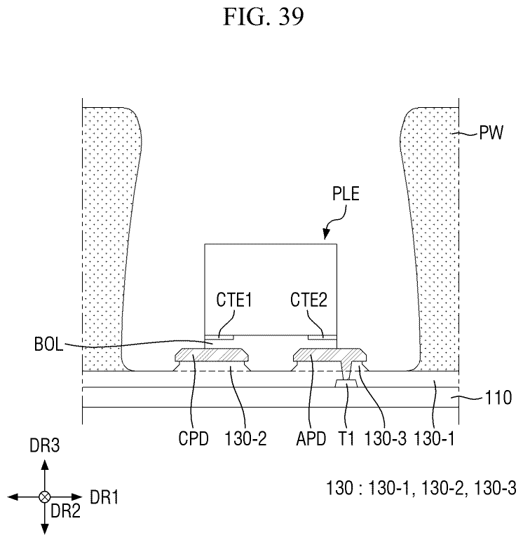

FIGS. 39 to 43 are diagrams to illustrate a manufacturing method of a display device according to another embodiment.

FIGS. 39 to 43 illustrate the structure of each layer of the display device 10 in cross-sectional views. FIGS. 39 to 43 focus on the manufacturing process of the light emitting element part LEP, which may substantially correspond to the cross-sectional view of FIG. 13. Additionally, the following description will focus on the first light emitting area EA1 of the display device 10.

First, the flip-chip type light emitting element PLE is bonded on the second planarization layer 130 having an undercut-shaped structure by the organic pattern layer BOL.

The method of forming the second planarization layer 130 having the undercut-shaped structure was described with reference to FIG. 29, and the method of bonding the flip-chip type light emitting element PLE by the organic pattern layer BOL may be the same as the method of bonding the light emitting element LE by the organic patterned layer BOL with reference to FIGS. 30 to 32, and a redundant description thereof will be omitted.

Next, referring to FIG. 39, a partition wall PW is formed on the second planarization layer 130 on which the flip-chip type light emitting element PLE is disposed.

In an embodiment, the partition wall PW is formed on the second planarization layer 130 using a negative photoresist. The portion of the negative photoresist that does not receive light is dissolved, and the partition wall PW may be formed in an inverted tapered shape with a width narrowing downward.

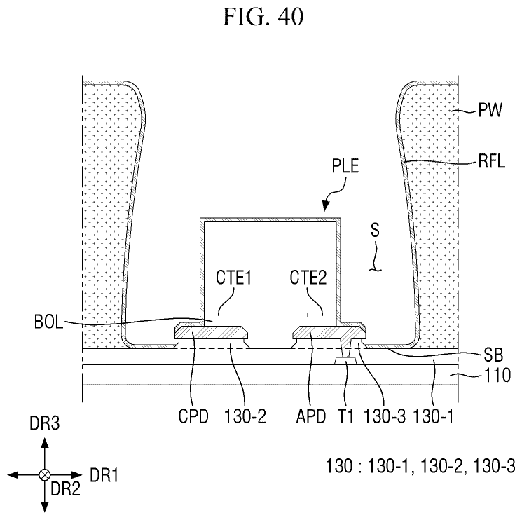

Next, referring to FIG. 40, in an embodiment, a reflective material layer RFL is deposited on the entire surface of the substrate 110 on which the partition wall PW is formed. The reflective material layer RFL may be formed to cover both the partition wall and the light emitting element LE.

The reflective material layer RFL is formed on top and side surfaces of the partition wall PW, top and side surfaces of the light emitting element LE, as well as on a bottom (top surface of the second planarization layer 130) between the flip-chip type light emitting element PLE and the partition wall PW. The reflective material layer RFL is disposed along the side of the flip-chip type light emitting element PLE, the side of the first contact electrode CTE1, the side of the second contact electrode CTE2, the side of the organic pattern layer BOL, the side of the first pad electrode CPD, and the side of the second pad electrode APD, but is cut off by an undercut-shaped structure of the second planarization portion 130-2 and the third planarization portion 130-3 of the second planarization layer 130. The reflective material layer RFL disposed along the side surface of the light emitting element LE, the side of the first contact electrode CTE1, the side of the second contact electrode CTE2, the side of the organic pattern layer BOL, the side of the first pad electrode CPD, and the side of the second pad electrode APD and the reflective material layer RFL deposited on the bottom surface SB of the space S formed by the partition wall PW are discontinuously disposed. The reflective material layer RFL disposed along the side surface of the light emitting element LE, the side of the first contact electrode CTE1, the side of the second contact electrode CTE2, the side of the organic pattern layer BOL, the side of the first pad electrode CPD, and the side of the second pad electrode APD may be spaced apart from the reflective material layer RFL deposited on the bottom surface SB of the space S formed by the partition wall PW. The reflective material layer RFL may include, for example, aluminum (Al) or silver (Ag), or may be an alloy thereof.

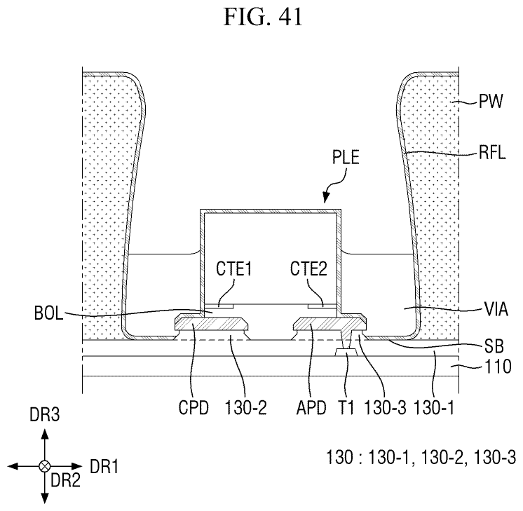

Next, referring to FIG. 41, a via layer VIA is formed in the space formed by the partition wall PW. The via layer VIA may be applied using a solution process, such as spin coating or inkjet printing. The via layer VIA may be formed lower than a height of the light emitting element LE. For example, a top surface of the light emitting element LE may be higher than the via layer VIA.

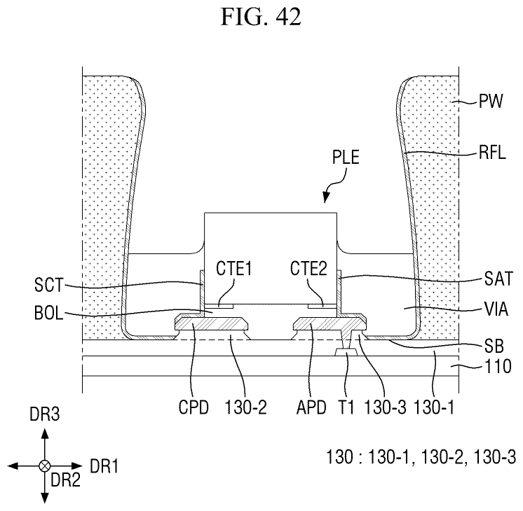

Referring to FIG. 42, a portion of the reflective material layer RFL is removed to form a reflective layer RF on the side of the partition wall PW, and a first auxiliary connection electrode SCT and a second auxiliary connection electrode SAT are formed.

A second etch to partially remove the reflective material layer RFL is performed to form the reflective layer RF, the first auxiliary connection electrode SCT, and the second auxiliary connection electrode SAT.

For example, a portion of the reflective material layer RFL on the flip-chip type light emitting element PLE and protruding above the via layer VIA may be removed.

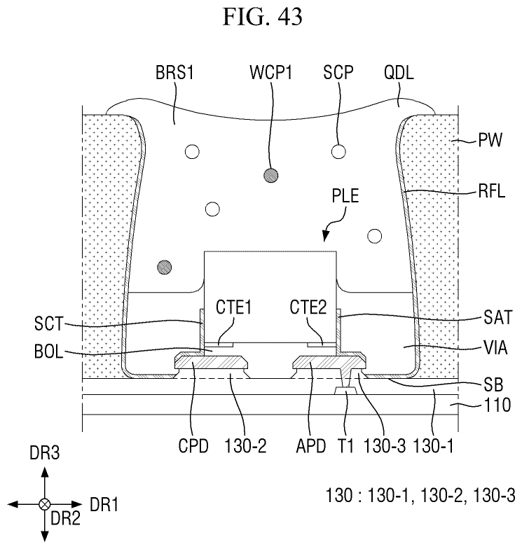

Referring to FIG. 43, a wavelength conversion layer QDL is formed in the space formed within the partition wall PW.

For example, a solution mixed with a first base resin BRS1, a first wavelength conversion particle WCP1, and a scatterer SCP may be dripped in the space formed in the partition wall PW by a solution process such as inkjet printing, imprinting, or the like, but is not limited thereto. Each wavelength conversion layer QDL may be formed within a plurality of openings and may be formed to overlap a plurality of light emitting areas.

Thereafter, a capping layer CAP, a first overcoat layer OC1, a color filter, and a second overcoat layer OC2 are formed on the partition wall PW and the wavelength conversion layer QDL, as shown in FIG. 12.

The color filter may be formed through a photolithography process. In an embodiment, the thickness of the color filter may be 1 μm or less, but is not limited thereto. Similarly, other color filters are also formed to overlap each opening through a patterning process.

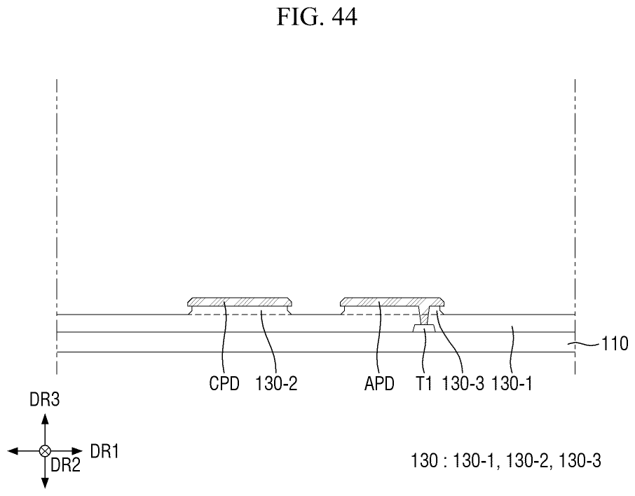

FIGS. 44 to 50 are diagrams to illustrate a manufacturing method of a display device according to another embodiment.

FIGS. 44 to 50 each illustrate a cross-sectional view of the structure of each layer of the display device 10 in the order of formation. FIGS. 44 to 50 focus on a manufacturing process of the light emitting element part LEP, which may substantially correspond to the cross-sectional view of FIG. 17. Additionally, the following description will focus on the first light emitting area EA1 of the display device 10.

Referring to FIG. 44, a second planarization layer 130 having an undercut-shaped structure is formed. The second planarization layer 130 having the undercut-shaped structure may be the same as that described with reference to FIG. 29, and further detailed description will be omitted.

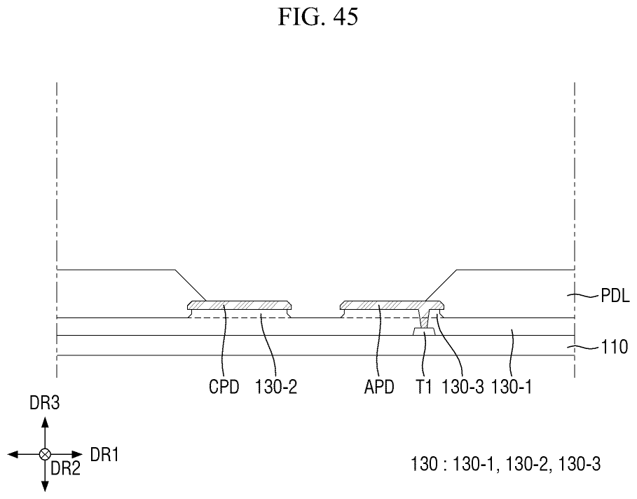

Referring to FIG. 45, a bank PDL may be formed on the second planarization layer 130. In an embodiment, the banks PDL may be formed through a photolithography process. The bank PDL may be formed of an organic film, such as an acrylic resin, epoxy resin, phenolic resin, polyamide resin, polyimide resin, or the like.

The bank PDL may be formed to cover the edges of the first pad electrode CPD and the second pad electrode APD. The bank PDL may include an inclined part that overlaps the edges of the first pad electrode CPD and the second pad electrode APD and has a slope (e.g., a predetermined slope), and a flat part that extends from the inclined part and has a flat plane.

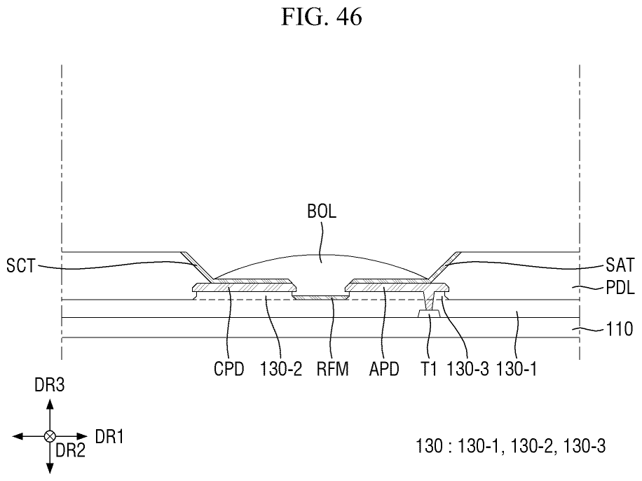

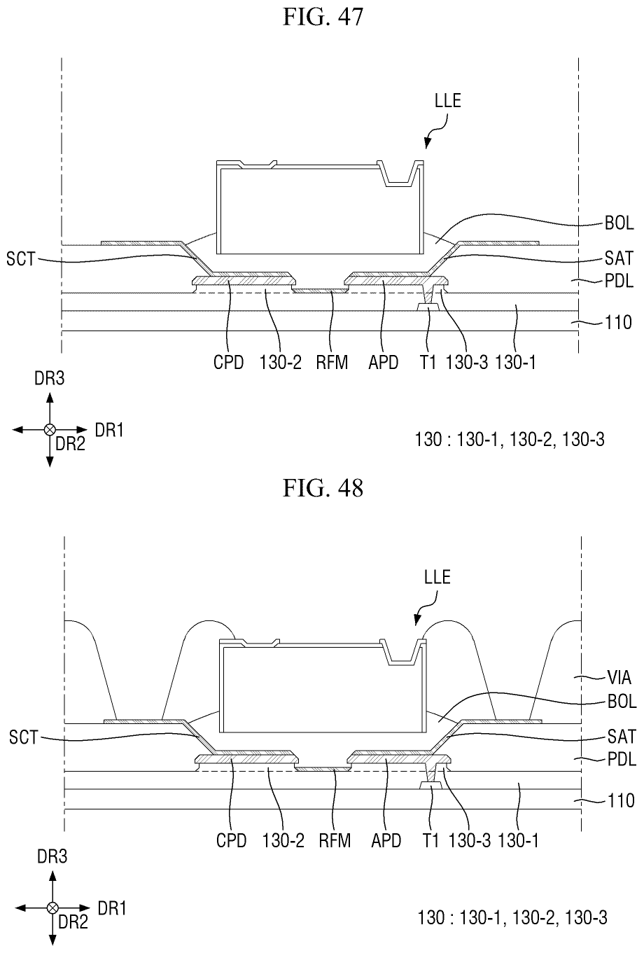

Next, referring to FIGS. 46 and 47, a first auxiliary connection electrode SCT, a second auxiliary connection electrode SAT and a horizontal reflective layer RFM may be formed on the bank PDL and the first pad electrode CPD and the second pad electrode APD. The first auxiliary connection electrode SCT, the second auxiliary connection electrode SAT and the horizontal reflective layer RFM may be formed by the same process, and the first auxiliary connection electrode SCT and the second auxiliary connection electrode SAT may be disconnected from the horizontal reflective layer RFM through the undercut structure. An organic pattern material layer BOL may be formed, and a lateral light emitting element LLE may be bonded.

The organic pattern material layer BOL is formed to cover the first pad electrode CPD and the second pad electrode APD and is disposed on the lateral light emitting element LLE on the organic pattern material layer BOL. The lateral light emitting element LLE is disposed on the organic pattern material layer BOL such that the first contact electrode CTE1 and the second contact electrode CTE2 are facing upward. The first contact electrode CTE1 may be disposed close to the first pad electrode CPD, and the second contact electrode CTE2 may be disposed close to the second pad electrode APD. Thereafter, the lateral light emitting element LLE may be bonded to the second planarization layer 130 by curing the organic pattern material layer BOL.

Next, referring to FIG. 48, a via layer VIA that partially exposes the first auxiliary connection electrode SCT, and the second auxiliary connection electrode SAT may be formed. In an embodiment, a height of the via layer VIA may be formed to be higher than a height of the lateral light emitting element LLE, but is not limited to thereto.

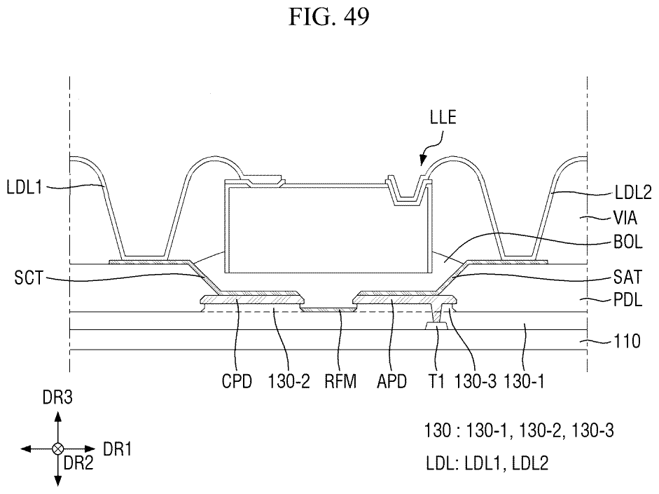

Referring to FIG. 49, a first lead line LDL1 connecting a first contact electrode CTE1 of the lateral light emitting element LLE and a first auxiliary connection electrode SCT is formed, and a second lead line LDL2 connecting a second contact electrode CTE2 and a second auxiliary connection electrode SAT is formed. An end of the first lead line LDL1 is disposed on the first contact electrode CTE1 and is disposed along the via layer VIA, while another end is disposed on the first auxiliary connection electrode SCT. An end of the second lead line LDL2 is disposed on the second contact electrode CTE2 and is disposed along the via layer VIA, while another end is disposed on the second auxiliary connection electrode SAT.

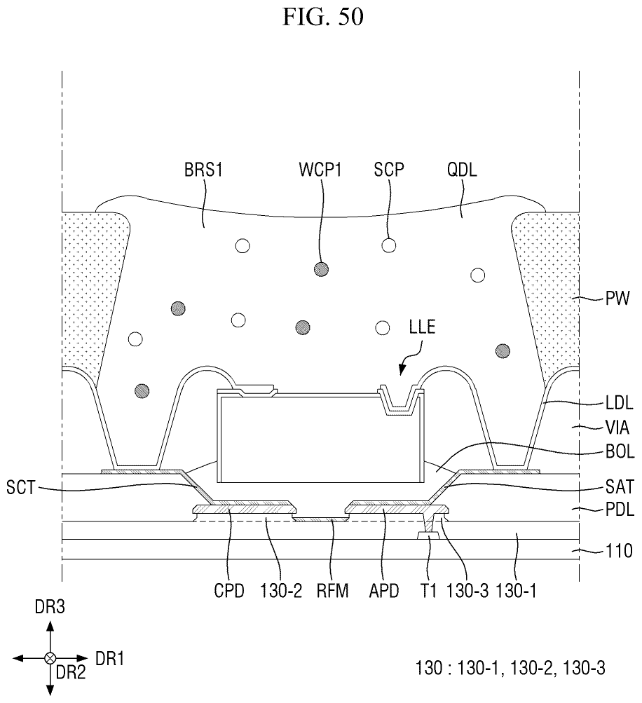

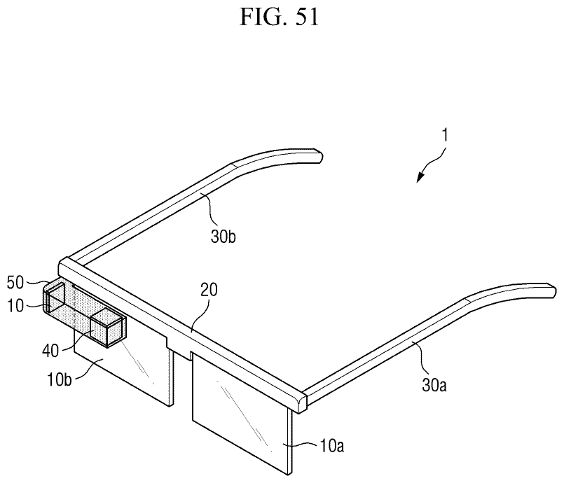

Referring to FIG. 50, a partition wall PW and a wavelength conversion layer QDL are formed on the via layer VIA.

In an embodiment, the partition wall PW is formed on the second planarization layer 130 using a negative photoresist. The portion of the negative photoresist that does not receive light is dissolved, and the partition wall PW may be formed in an inverted tapered shape with a width narrowing downward.

The wavelength conversion layer QDL is formed in the space formed within the partition wall PW. For example, a solution mixed with a first base resin BRS1, a first wavelength conversion particle WCP1, and a scatterer SCP may be dripped in the space formed in the partition wall PW by a solution process such as inkjet printing, imprinting, or the like, but is not limited thereto. Each wavelength conversion layer QDL may be formed within a plurality of openings and may be formed to overlap a plurality of light emitting areas.

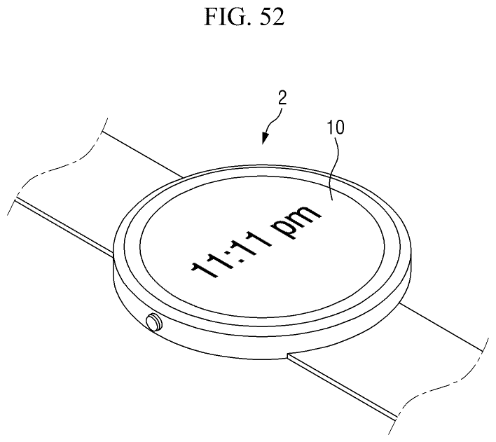

FIG. 51 is a diagram illustrating an example of a virtual reality device including a display device according to an embodiment. FIG. 51 illustrates a virtual reality device 1 in which the display device 10 according to an embodiment is included.

Referring to FIG. 51, the virtual reality device 1 according to an embodiment may be a device in a form of glasses. The virtual reality device 1 according to an embodiment may include a display device 10, a left-eye lens 10a, a right-eye lens 10b, a support frame 20, left and right legs 30a and 30b, a reflective member 40, and a display device housing 50.

FIG. 51 illustrates the virtual reality device 1 including the two legs 30a and 30b. However, the disclosure is not limited thereto. For example, the virtual reality device 1 according to an embodiment may be used in a head-mounted display including a head-mounted band that may be mounted on a head instead of the legs 30a and 30b. For example, the virtual reality device 1 according to an embodiment may not be limited to the example shown in FIG. 51, and may be applied in various forms and in various electronic devices.

The display device housing 50 may receive the display device 10 and the reflective member 40. An image displayed on the display device 10 may be reflected from the reflective member 40 and provided to a user's right eye through the right-eye lens 10b. Thus, the user may view a virtual reality image displayed on the display device 10 via the right eye.

FIG. 51 illustrates that the display device housing 50 is disposed at a right end of the support frame 20. However, embodiments of the disclosure are not limited thereto. For example, the display device housing 50 may be disposed at a left end of the support frame 20. In this case, the image displayed on the display device 10 may be reflected from the reflective member 40 and provided to the user's left eye via the left-eye lens 10a. Thus, the user may view the virtual reality image displayed on the display device 10 via the left eye. As another example, the display device housing 50 may be disposed at each of the left end and the right end of the support frame 20. In this case, the user may view the virtual reality image displayed on the display device 10 via both the left eye and the right eye.

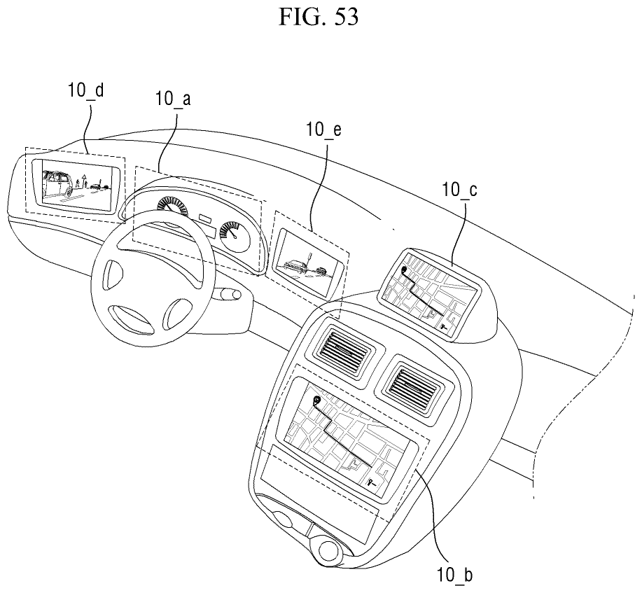

FIG. 52 is a diagram illustrating an example of a smart device including a display device according to an embodiment.

Referring to FIG. 52, a display device 10 according to an embodiment may be applied to a smart watch 2 as an example of a smart device.

FIG. 53 is a diagram illustrating an example of a vehicle including a display device according to an embodiment. FIG. 53 illustrates a vehicle in which display devices 10_a, 10_b, 10_c, 10_d and 10_e according to an embodiment are included.

Referring to FIG. 53, display devices 10_a, 10_b, and 10_c according to an embodiment may be applied to a dashboard of the vehicle, applied to a center fascia of the vehicle, or applied to a CID (Center Information Display) disposed on the dashboard of the vehicle. Further, each of display devices 10_d and 10_e according to an embodiment may be applied to each room mirror display that replaces each of side-view mirrors of the vehicle.

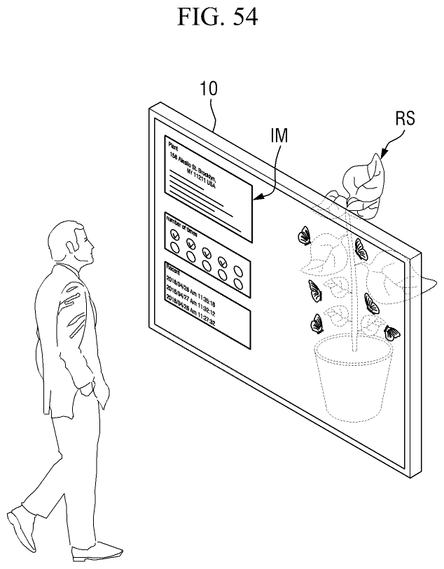

FIG. 54 is a diagram illustrating an example of a transparent display device including a display device according to an embodiment.

Referring to FIG. 54, a display device 10 according to an embodiment may be applied to a transparent display device. The transparent display device may transmit light therethrough while displaying an image IM thereon. Therefore, a user located in front of the transparent display device may not only view the image IM displayed on the display device 10, but also view an object RS or a background located at a rear of the transparent display device. In a case in which the display device 10 is applied to the transparent display device, the substrate 110 of the display device 10 shown in FIG. 6 may include a light transmitting portion that may transmit light therethrough or may be made of a material that may transmit light therethrough.

Although some embodiments have been described in the above detailed description, those skilled in the art will appreciate that many variations and modifications can be made to the embodiments without substantially departing from the principles of the disclosure. Therefore, the disclosed embodiments of the disclosure may be understood to be used in a generic and descriptive sense and not for purposes of limitation.

What is claimed is:

1. A display device comprising:
a planarization layer comprising a first planarization part on a substrate, and a second planarization part and a third planarization part on the first planarization part;
a first pad electrode on the second planarization part, and a second pad electrode on the third planarization part;
an organic pattern layer on the first pad electrode and the second pad electrode;
a light emitting element on the organic pattern layer and comprising a first semiconductor layer, an active layer, and a second semiconductor layer;
a partition wall on a surface of the first planarization part and defining a space around the light emitting element;
a reflective layer on a side of the partition wall and the first planarization part within the space;
a first auxiliary connection electrode connecting the second semiconductor layer and the first pad electrode; and
a second auxiliary connection electrode connecting the first semiconductor layer and the second pad electrode,
wherein the planarization layer has an undercut shape in which a side surface of the second planarization part is recessed towards a center of the first pad electrode, and a side surface of the third planarization part is recessed towards a center of the second pad electrode.

2. The display device of claim 1, wherein the reflective layer comprises a first reflective layer on a side of the partition wall and a second reflective layer on an upper portion of the first planarization part,
wherein the second reflective layer extends from the first reflective layer and is disconnected from the first auxiliary connection electrode and the second auxiliary connection electrode by the undercut shape.

3. The display device of claim 2, wherein the first auxiliary connection electrode and the second auxiliary connection electrode comprise a same material as the reflective layer.

4. The display device of claim 2, wherein the first pad electrode and the second pad electrode are spaced apart from each other on a same plane and protrude outward from the light emitting element.

5. The display device of claim 4, wherein the light emitting element further comprises,
an element reflective layer on a bottom surface of the first semiconductor layer;
an element insulating layer around sides of the element reflective layer, the first semiconductor layer, the active layer, and the second semiconductor layer; and
a pad connection electrode on a bottom surface of the element reflective layer, a first end of which is in direct contact with the second auxiliary connection electrode.

6. The display device of claim 5, wherein the first auxiliary connection electrode comprises a first end on a top surface of the second semiconductor layer, extends along a side of the light emitting element and a side of the organic pattern layer, and further comprises a second end on a side of the first pad electrode,
wherein the second auxiliary connection electrode comprises a first end on the side of the light emitting element, extends along the side of the light emitting element, the first end of the pad connection electrode, and a side of the organic pattern layer, and further comprises a second end on a side of the second pad electrode.

7. The display device of claim 6, further comprising a via layer and a wavelength conversion layer sequentially arranged in the space,
wherein a height of the second auxiliary connection electrode is equal to or lower than a height of the via layer.

8. The display device of claim 4, wherein the light emitting element further comprises,
a base substrate on the second semiconductor layer,
a first contact electrode on a first surface of the second semiconductor layer, and
a second contact electrode on a first surface of the first semiconductor layer, and
wherein the first contact electrode and the second contact electrode are arranged to be spaced apart from each other and are bonded to the organic pattern layer.

9. The display device of claim 8, wherein the first auxiliary connection electrode comprises a first end on a side of the light emitting element, extends along the side of the light emitting element, a first end of the first contact electrode, and a side of the organic pattern layer, and further comprises a second end on a side of the first pad electrode,
wherein the second auxiliary connection electrode comprises a first end on a side of the light emitting element, extends along the side of the light emitting element, a first end of the second contact electrode, and a side of the organic pattern layer, and further comprises a second end on a side of the second pad electrode.

10. The display device of claim 9, further comprising a via layer and a wavelength conversion layer sequentially arranged in the space,
wherein a height of the first auxiliary connection electrode and a height of the second auxiliary connection electrode are equal to or lower than a height of the via layer.

11. The display device of claim 3, further comprising:
a via layer and a wavelength conversion layer sequentially arranged within the space; and
a capping layer, an overcoat layer, and a color filter layer sequentially arranged on the wavelength conversion layer and the partition wall.

12. A display device comprising:
a planarization layer comprising a first planarization part on a substrate, and a second planarization part and a third planarization part on the first planarization part;
a first pad electrode on the second planarization part, and a second pad electrode on the third planarization part;
a bank covering a portion of the first pad electrode and a portion of the second pad electrode;
a first auxiliary connection electrode comprising a first end in contact with the first pad electrode and a second end on a top surface of the bank;
a second auxiliary connection electrode comprising a first end in contact with the second pad electrode and a second end on the top surface of the bank;
an insulating organic layer overlapping the first pad electrode and the second pad electrode and covering a portion of the first auxiliary connection electrode and a portion of the second auxiliary connection electrode;
a light emitting element on the insulating organic layer and comprising a first contact electrode and a second contact electrode on a top surface thereof; and
first and second lead lines respectively connecting the first contact electrode to the first auxiliary connection electrode and connecting the second contact electrode to the second auxiliary connection electrode,
wherein the second planarization part has an undercut shape in which a side surface of the second planarization part is recessed towards a center of the first pad electrode, the third planarization part has an undercut shape in which a side surface of the third planarization part is recessed towards a center of the second pad electrode, and a horizontal reflective layer is located between the second planarization part and the third planarization part.

13. The display device of claim 12, wherein the horizontal reflective layer is located between the first auxiliary connection electrode and the second auxiliary connection electrode and is disconnected from the first auxiliary connection electrode and the second auxiliary connection electrode by the undercut shape of the second planarization part and the undercut shape of the third planarization part.

14. The display device of claim 13, wherein the horizontal reflective layer comprises a same material as the first auxiliary connection electrode and the second auxiliary connection electrode.

15. The display device of claim 12, wherein the light emitting element further comprises a first semiconductor layer, an active layer, a second semiconductor layer, and an element insulating layer,
wherein the element insulating layer surrounds sides of the first semiconductor layer, the active layer, and the second semiconductor layer,
wherein the first contact electrode is in contact with the first semiconductor layer, and the second contact electrode is in contact with the second semiconductor layer.

16. The display device of claim 15, wherein a first end of the first lead line is on the first contact electrode and a second end of the first lead line is on the first auxiliary connection electrode, and
wherein a first end of the second lead line is on the second contact electrode and a second end of the second lead line is on the second auxiliary connection electrode.

17. A method of manufacturing a display device, the method comprising:
disposing a first planarization part, and a second planarization part and a third planarization part on the first planarization part, disposing a first pad electrode and a second pad electrode on the second planarization part and the third planarization part, respectively, etching the second planarization part and the third planarization part to expose the first planarization part, forming an undercut shape in which side surfaces of the second and third planarization parts are recessed towards centers of the first and second pad electrodes, respectively;
disposing an organic pattern layer and a light emitting element on the first pad electrode and the second pad electrode;
forming a partition wall on the first planarization part to be around the light emitting element;
depositing a reflective material layer to cover both the partition wall and the light emitting element;
forming a via layer in a space defined by the partition wall, forming a photoresist mask pattern to cover a portion of the light emitting element; and
forming a first auxiliary connection electrode and a second auxiliary connection electrode and a reflective layer by etching a reflective material layer on the via layer and the photoresist mask pattern.

18. The method of claim 17, wherein the reflective layer comprises a first reflective layer on a side of the partition wall, and a second reflective layer on an upper portion of the first planarization part,
wherein the second reflective layer is disposed to extend from the first reflective layer and is disconnected from the first auxiliary connection electrode and the second auxiliary connection electrode by the undercut shape.

19. The method of claim 17,
the disposing of the organic pattern layer and the light emitting element on the first pad electrode and the second pad electrode includes:
applying an organic pattern material layer on a substrate to cover the first planarization part, the second planarization part, the third planarization part, the first pad electrode, and the second pad electrode;
disposing the light emitting element to overlap the first pad electrode and the second pad electrode on the organic pattern material layer;
bonding the light emitting element by curing the organic pattern material layer; and
forming the organic pattern layer by ashing a portion of the organic pattern material layer not overlapping with the light emitting element.

20. The method of claim 17, further comprising:
forming a wavelength conversion layer in the space defined by the partition wall; and
forming an overcoat layer and a color filter layer sequentially arranged on the partition wall and the wavelength conversion layer.
